(19) United States
(12) Patent Application Publication
(10) Pub. No.: US 2024/0260253 A1
(43) Pub. Date: Aug. 1, 2024

(54) SEMICONDUCTOR MEMORY DEVICE

(71) Applicant: Kioxia Corporation, Tokyo (JP)

(72) Inventors: Mutsumi OKAJIMA, Yokkaichi (JP); Takafumi MASUDA, Kawasaki (JP); Nobuyoshi SAITO, Tokyo (JP); Keiji IKEDA, Kawasaki (JP)

(73) Assignee: Kioxia Corporation, Tokyo (JP)

(21) Appl. No.: 18/423,110

(22) Filed: Jan. 25, 2024

(30) Foreign Application Priority Data
Jan. 27, 2023 (JP) 2023-011420

(51) Int. Cl. H10B 12/00

(52) U.S. Cl. CPC H10B 12/30; H10B 12/03; H10B 12/05

(57) ABSTRACT

A semiconductor memory device comprises: a substrate;

memory layers arranged in a first direction intersecting with a surface of the substrate; and a first via wiring extending in the first direction. The memory layers each comprise: a first semiconductor layer electrically connected to the first via wiring; a first gate electrode facing surfaces on one side and the other side in the first direction of the first semiconductor layer; a memory portion which is provided on one side in a second direction intersecting with the first direction with respect to the first semiconductor layer, and is electrically connected to the first semiconductor layer; and a first wiring which is provided on the other side in the second direction with respect to the first semiconductor layer, is electrically connected to the first gate electrode, and extends in a third direction intersecting with the first direction and the second direction.

### CROSS-REFERENCE TO RELATED APPLICATIONS

This application is based upon and claims the benefit of Japanese Patent Application No. 2023-011420, filed on Jan. 27, 2023, the entire contents of which are incorporated herein by reference.

### BACKGROUND

### Field

Embodiments relate to a semiconductor memory device.

### Description of the Related Art

As degree-of-integration of semiconductor memory devices continues to rise, study is underway into how three-dimensionality of the semiconductor memory devices may be further promoted.

### BRIEF DESCRIPTION OF THE DRAWINGS

FIG. 1 is a schematic circuit diagram showing a part of a configuration of a semiconductor memory device according to a first embodiment.

FIG. 2 is a schematic perspective view showing a part of a configuration of the semiconductor memory device.

FIG. 3 is a schematic perspective view showing a part of a configuration of the semiconductor memory device.

FIG. 4 is a schematic XY cross-sectional view showing a part of a configuration of the semiconductor memory device.

FIG. 5 is a schematic cross-sectional view showing a part of a configuration of the semiconductor memory device.

FIG. 6 is a schematic cross-sectional view for explaining a method of manufacturing the semiconductor memory device.

FIG. 7 is a schematic cross-sectional view for explaining the method of manufacturing.

FIG. 8 is a schematic cross-sectional view for explaining the method of manufacturing.

FIG. 9 is a schematic cross-sectional view for explaining the method of manufacturing.

FIG. 10 is a schematic cross-sectional view for explaining the method of manufacturing.

FIG. 11 is a schematic cross-sectional view for explaining the method of manufacturing.

FIG. 12 is a schematic cross-sectional view for explaining the method of manufacturing.

FIG. 13 is a schematic cross-sectional view for explaining the method of manufacturing.

FIG. 14 is a schematic cross-sectional view for explaining the method of manufacturing.

FIG. 15 is a schematic cross-sectional view for explaining the method of manufacturing.

FIG. 16 is a schematic cross-sectional view for explaining the method of manufacturing.

FIG. 17 is a schematic cross-sectional view for explaining the method of manufacturing.

FIG. 18 is a schematic cross-sectional view for explaining the method of manufacturing.

FIG. 19 is a schematic cross-sectional view for explaining the method of manufacturing.

FIG. 20 is a schematic cross-sectional view for explaining the method of manufacturing.

FIG. 21 is a schematic cross-sectional view for explaining the method of manufacturing.

FIG. 22 is a schematic cross-sectional view for explaining the method of manufacturing.

FIG. 23 is a schematic cross-sectional view for explaining the method of manufacturing.

FIG. 24 is a schematic cross-sectional view for explaining the method of manufacturing.

FIG. 25 is a schematic cross-sectional view for explaining the method of manufacturing.

FIG. 26 is a schematic cross-sectional view for explaining the method of manufacturing.

FIG. 27 is a schematic cross-sectional view for explaining the method of manufacturing.

FIG. 28 is a schematic cross-sectional view for explaining the method of manufacturing.

FIG. 29 is a schematic cross-sectional view for explaining the method of manufacturing.

FIG. 30 is a schematic cross-sectional view for explaining the method of manufacturing.

FIG. 31 is a schematic cross-sectional view for explaining the method of manufacturing.

FIG. 32 is a schematic cross-sectional view for explaining the method of manufacturing.

FIG. 33 is a schematic cross-sectional view for explaining the method of manufacturing.

FIG. 34 is a schematic cross-sectional view for explaining the method of manufacturing.

FIG. 35 is a schematic cross-sectional view for explaining the method of manufacturing.

FIG. 36 is a schematic cross-sectional view for explaining the method of manufacturing.

FIG. 37 is a schematic cross-sectional view for explaining the method of manufacturing.

FIG. 38 is a schematic cross-sectional view for explaining the method of manufacturing.

FIG. 39 is a schematic cross-sectional view for explaining the method of manufacturing.

FIG. 40 is a schematic cross-sectional view for explaining the method of manufacturing.

FIG. 41 is a schematic cross-sectional view for explaining the method of manufacturing.

FIG. 42 is a schematic cross-sectional view for explaining the method of manufacturing.

FIG. 43 is a schematic cross-sectional view for explaining the method of manufacturing.

FIG. 44 is a schematic cross-sectional view for explaining the method of manufacturing.

FIG. 45 is a schematic cross-sectional view for explaining the method of manufacturing.

FIG. 46 is a schematic cross-sectional view for explaining the method of manufacturing.

FIG. 47 is a schematic cross-sectional view for explaining the method of manufacturing.

FIG. 48 is a schematic cross-sectional view for explaining the method of manufacturing.

FIG. 49 is a schematic cross-sectional view for explaining the method of manufacturing.

FIG. 50 is a schematic cross-sectional view for explaining the method of manufacturing.

FIG. 51 is a schematic cross-sectional view for explaining the method of manufacturing.

FIG. 52 is a schematic cross-sectional view for explaining the method of manufacturing.

FIG. 53 is a schematic cross-sectional view for explaining the method of manufacturing.

FIG. 54 is a schematic cross-sectional view for explaining the method of manufacturing.

FIG. 55 is a schematic cross-sectional view for explaining the method of manufacturing.

FIG. 56 is a schematic cross-sectional view for explaining the method of manufacturing.

FIG. 57 is a schematic cross-sectional view for explaining the method of manufacturing.

FIG. 58 is a schematic cross-sectional view for explaining the method of manufacturing.

FIG. 59 is a schematic cross-sectional view for explaining the method of manufacturing.

FIG. 60 is a schematic cross-sectional view showing a part of a configuration of a semiconductor memory device according to a second embodiment.

FIG. 61 is a schematic XY cross-sectional view showing a part of a configuration of a semiconductor memory device according to a third embodiment.

FIG. 62 is a schematic cross-sectional view showing a part of a configuration of the semiconductor memory device.

FIG. 63 is a schematic cross-sectional view for explaining a method of manufacturing the semiconductor memory device.

FIG. 64 is a schematic cross-sectional view for explaining the method of manufacturing.

FIG. 65 is a schematic cross-sectional view for explaining the method of manufacturing.

FIG. 66 is a schematic cross-sectional view for explaining the method of manufacturing.

FIG. 67 is a schematic cross-sectional view for explaining the method of manufacturing.

FIG. 68 is a schematic cross-sectional view for explaining the method of manufacturing.

FIG. 69 is a schematic cross-sectional view for explaining the method of manufacturing.

FIG. 70 is a schematic cross-sectional view for explaining the method of manufacturing.

FIG. 71 is a schematic cross-sectional view for explaining the method of manufacturing.

FIG. 72 is a schematic cross-sectional view for explaining the method of manufacturing.

FIG. 73 is a schematic cross-sectional view for explaining the method of manufacturing.

FIG. 74 is a schematic cross-sectional view for explaining the method of manufacturing.

FIG. 75 is a schematic cross-sectional view for explaining the method of manufacturing.

FIG. 76 is a schematic cross-sectional view for explaining the method of manufacturing.

FIG. 77 is a schematic cross-sectional view for explaining the method of manufacturing.

FIG. 78 is a schematic cross-sectional view for explaining the method of manufacturing.

FIG. 79 is a schematic cross-sectional view for explaining the method of manufacturing.

FIG. 80 is a schematic cross-sectional view for explaining the method of manufacturing.

FIG. 81 is a schematic cross-sectional view for explaining the method of manufacturing.

FIG. 82 is a schematic cross-sectional view for explaining the method of manufacturing.

FIG. 83 is a schematic cross-sectional view for explaining the method of manufacturing.

FIG. 84 is a schematic cross-sectional view for explaining the method of manufacturing.

FIG. 85 is a schematic cross-sectional view for explaining the method of manufacturing.

FIG. 86 is a schematic cross-sectional view for explaining the method of manufacturing.

FIG. 87 is a schematic cross-sectional view for explaining the method of manufacturing.

FIG. 88 is a schematic cross-sectional view for explaining the method of manufacturing.

FIG. 89 is a schematic cross-sectional view for explaining the method of manufacturing.

FIG. 90 is a schematic cross-sectional view for explaining the method of manufacturing.

FIG. 91 is a schematic cross-sectional view for explaining the method of manufacturing.

FIG. 92 is a schematic cross-sectional view for explaining the method of manufacturing.

FIG. 93 is a schematic cross-sectional view for explaining the method of manufacturing.

FIG. 94 is a schematic cross-sectional view for explaining the method of manufacturing.

FIG. 95 is a schematic cross-sectional view for explaining the method of manufacturing.

FIG. 96 is a schematic cross-sectional view for explaining the method of manufacturing.

FIG. 97 is a schematic cross-sectional view for explaining the method of manufacturing.

FIG. 98 is a schematic cross-sectional view for explaining the method of manufacturing.

FIG. 99 is a schematic cross-sectional view for explaining the method of manufacturing.

FIG. 100 is a schematic cross-sectional view for explaining the method of manufacturing.

FIG. 101 is a schematic cross-sectional view for explaining the method of manufacturing.

FIG. 102 is a schematic cross-sectional view for explaining the method of manufacturing.

FIG. 103 is a schematic cross-sectional view for explaining the method of manufacturing.

FIG. 104 is a schematic cross-sectional view for explaining the method of manufacturing.

FIG. 105 is a schematic cross-sectional view for explaining the method of manufacturing.

FIG. 106 is a schematic cross-sectional view for explaining the method of manufacturing.

FIG. 107 is a schematic cross-sectional view for explaining the method of manufacturing.

FIG. 108 is a schematic cross-sectional view for explaining the method of manufacturing.

FIG. 109 is a schematic cross-sectional view for explaining the method of manufacturing.

FIG. 110 is a schematic cross-sectional view for explaining the method of manufacturing.

FIG. 111 is a schematic cross-sectional view for explaining the method of manufacturing.

FIG. 112 is a schematic perspective view for explaining the method of manufacturing the semiconductor memory device according to the first embodiment.

FIG. 113 is a schematic perspective view for explaining a method of manufacturing a semiconductor memory device according to a fourth embodiment.

FIG. 114 is a schematic cross-sectional view for explaining the method of manufacturing.

FIG. 115 is a schematic cross-sectional view for explaining the method of manufacturing.

FIG. 116 is a schematic cross-sectional view for explaining the method of manufacturing.

FIG. 117 is a schematic cross-sectional view for explaining the method of manufacturing.

FIG. 118 is a schematic cross-sectional view for explaining the method of manufacturing.

FIG. 119 is a schematic cross-sectional view for explaining the method of manufacturing.

FIG. 120 is a schematic cross-sectional view for explaining the method of manufacturing.

FIG. 121 is a schematic cross-sectional view for explaining the method of manufacturing.

FIG. 122 is a schematic cross-sectional view for explaining the method of manufacturing.

FIG. 123 is a schematic XY cross-sectional view showing a part of a configuration of the semiconductor memory device according to the fourth embodiment.

FIG. 124 is a schematic cross-sectional view showing a part of a configuration of the semiconductor memory device.

FIG. 125 is a schematic circuit diagram showing a part of a configuration of a semiconductor memory device according to a fifth embodiment.

FIG. 126 is a schematic XY cross-sectional view showing a part of a configuration of the semiconductor memory device.

FIG. 127 is a schematic cross-sectional view showing a part of a configuration of the semiconductor memory device.

FIG. 128 is a schematic XY cross-sectional view showing a part of a configuration of a semiconductor memory device according to a sixth embodiment.

FIG. 129 is a schematic cross-sectional view showing a part of a configuration of the semiconductor memory device.

FIG. 130 is a schematic cross-sectional view showing a part of a configuration of the semiconductor memory device.

FIG. 131 is a schematic cross-sectional view showing a part of a configuration of a semiconductor memory device according to a seventh embodiment.

FIG. 132 is a schematic XY cross-sectional view showing configurations of a memory chip C_{M}.

FIG. 133 is a schematic plan view showing configurations of a peripheral circuit chip C_{C}.

### DETAILED DESCRIPTION

A semiconductor memory device according to one embodiment comprises: a substrate; a plurality of memory layers arranged in a first direction intersecting with a surface of the substrate; and a first via wiring extending in the first direction. The plurality of memory layers each comprise: a first semiconductor layer electrically connected to the first via wiring; a first gate electrode facing surfaces on one side and the other side in the first direction of the first semiconductor layer; a memory portion which is provided on one side in a second direction intersecting with the first direction with respect to the first semiconductor layer, and is electrically connected to the first semiconductor layer; and a first wiring which is provided on the other side in the second direction with respect to the first semiconductor layer, is electrically connected to the first gate electrode, and extends in a third direction intersecting with the first direction and the second direction.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been serially connected, the first transistor is still “electrically connected” to the third transistor even when the second transistor is in an OFF state.

Moreover, in the present specification, when a first configuration is said to be “electrically connected between” a second configuration and a third configuration, it will sometimes mean that the first configuration, the second configuration, and the third configuration are serially connected, and the second configuration is electrically connected to the third configuration via the first configuration.

Moreover, in the present specification, when a circuit, or the like, is said to “make electrically continuous” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting with the first direction along the certain plane will sometimes be referred to as a second direction, and a direction intersecting with the certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting with the X-direction or the Y-direction will be referred to as a side surface, and so on.

Moreover, in the present specification, when a “center position” of a certain configuration is referred to, it may mean a position of the center of a circumscribed circle of this configuration, or may mean the center of gravity on an image of this configuration, for example.

### First Embodiment

### [Circuit Configuration]

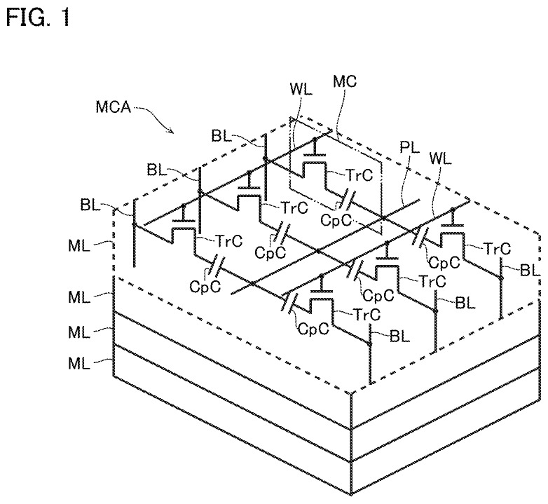

FIG. 1 is a schematic circuit diagram showing a part of a configuration of a semiconductor memory device according to a first embodiment. As shown in FIG. 1, the semiconductor memory device according to the present embodiment comprises a memory cell array MCA. The memory cell array MCA comprises: a plurality of memory layers ML; a plurality of bit lines BL connected to the plurality of memory layers ML; and a plate line PL connected to the plurality of memory layers ML.

The memory layers ML each comprise: a plurality of word lines WL; and pluralities of memory cells MC connected to the plurality of word lines WL. The memory cells MC each comprise a transistor TrC and a capacitor CpC. A source electrode of the transistor TrC is connected to the bit line BL. A drain electrode of the transistor TrC is connected to the capacitor CpC. A gate electrode of the transistor TrC is connected to the word line WL. One electrode of the capacitor CpC is connected to the drain electrode of the transistor TrC. The other electrode of the capacitor CpC is connected to the plate line PL. Each bit line BL is connected to a plurality of the memory cells MC corresponding to the plurality of memory layers ML.

### [Structure]

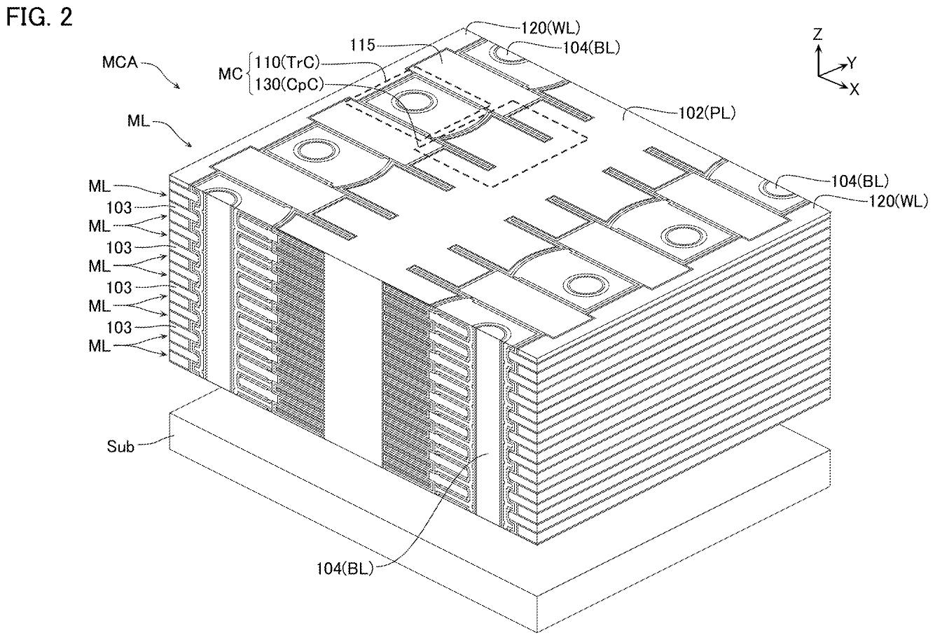

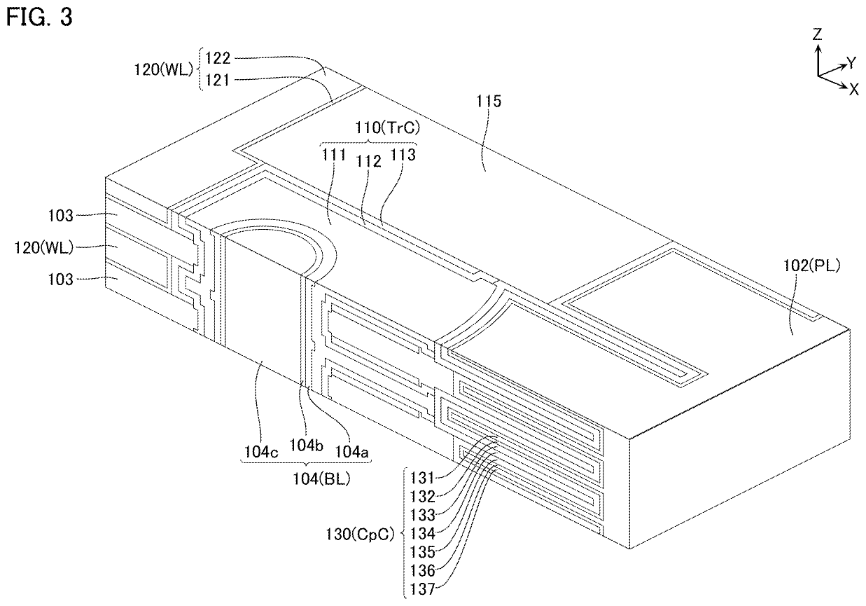

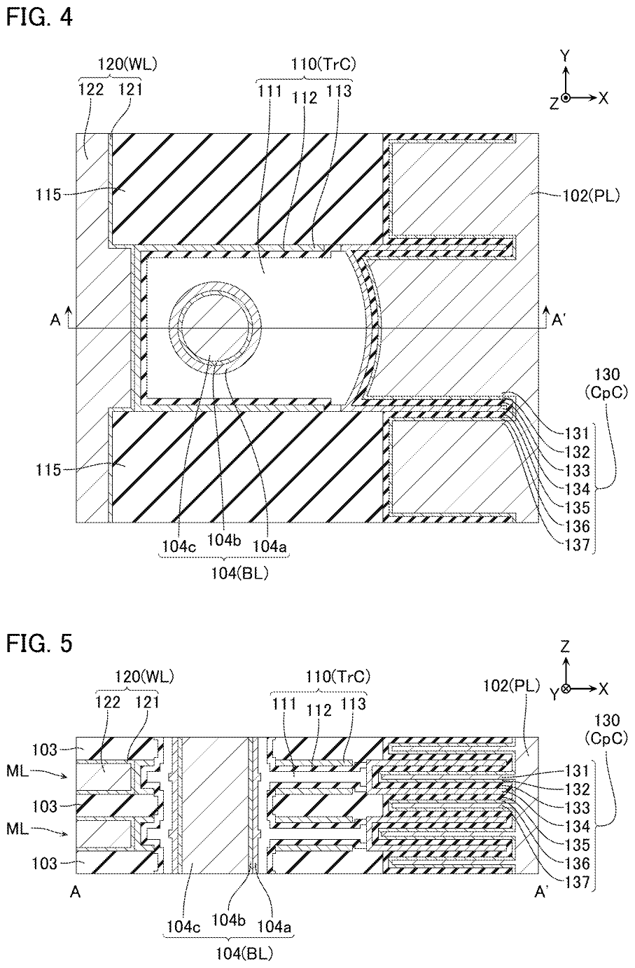

FIG. 2 is a schematic perspective view showing a part of a configuration of the semiconductor memory device according to the first embodiment. FIG. 3 is a schematic perspective view showing a part of a configuration of the semiconductor memory device, and shows an enlarged part of FIG. 2. FIG. 4 is a schematic XY cross-sectional view showing a part of a configuration of the semiconductor memory device. FIG. 5 is a schematic cross-sectional view showing a part of a configuration of the semiconductor memory device, and shows configurations when the structure shown in FIG. 4 has been cut along the line A-A′ and viewed along a direction of the arrows.

FIG. 2 shows: a part of a semiconductor substrate Sub; and the memory cell array MCA which is provided above the semiconductor substrate Sub.

The semiconductor substrate Sub is a semiconductor substrate of the likes of silicon (Si) containing a P type impurity such as boron (B), for example. An unillustrated insulating layer and an unillustrated electrode layer are provided on an upper surface of the semiconductor substrate Sub. The upper surface of the semiconductor substrate Sub, and the unillustrated insulating layer and the unillustrated electrode layer configure a control circuit for controlling the semiconductor memory device according to the first embodiment. For example, a region directly below the memory cell array MCA is provided with a sense amplifier circuit. The sense amplifier circuit is electrically connected to the bit line BL. The sense amplifier circuit detects change in voltage or current of the bit line BL in a read operation, and thereby enables data stored in a selected memory cell MC to be read in the read operation.

The memory cell array MCA comprises the plurality of memory layers ML which are arranged in the Z-direction. Moreover, insulating layers 103 of the likes of silicon oxide (SiO₂) are respectively provided between the plurality of memory layers ML.

Moreover, the memory cell array MCA is provided with a conductive layer 102. The conductive layer 102 extends in the Y-direction and the Z-direction, and divides the memory layer ML in the X-direction.

The conductive layer 102 includes the likes of a stacked structure of titanium nitride (TiN) and tungsten (W), for example. The conductive layer 102 functions as the plate line PL (FIG. 1), for example.

In addition, the memory cell array MCA is provided with a plurality of via wirings 104. The plurality of via wirings 104 are arranged in the Y-direction, and extend in the Z-direction penetrating the plurality of memory layers ML.

As shown in FIG. 3, the via wiring 104 includes, for example: a conductive oxide film 104a that includes a conductive oxide; a barrier conductive film 104b of the likes of titanium nitride (TiN); and a conductive member 104c of the likes of tungsten (W). Note that the via wiring 104 may include ruthenium (Ru), iridium (Ir), or another metal, instead of the conductive oxide film 104a. Moreover, the via wiring 104 may include solely a conductive oxide, or may include solely ruthenium (Ru), iridium (Ir), or another metal.

Note that in the present specification, a “conductive oxide” will be assumed to include indium tin oxide (ITO), indium zinc oxide (IZO), ruthenium oxide (RuO₂), iridium oxide (IrO₂), or another conductive material including oxygen, for example.

The conductive member 104c comprises a substantially circular column-like shape extending in the Z-direction. The barrier conductive film 104b comprises a substantially cylindrical shape extending in the Z-direction along an outer peripheral surface of the conductive member 104c. The conductive oxide film 104a comprises a substantially cylindrical shape extending in the Z-direction along an outer peripheral surface of the barrier conductive film 104b. The via wiring 104 functions as the bit line BL (FIG. 1), for example. As shown in FIG. 2, for example, a plurality of the bit lines BL are provided correspondingly to the plurality of transistors TrC included in the memory layers ML.

The memory layer ML comprises: a plurality of transistor structures 110 provided correspondingly to the plurality of via wirings 104; a conductive layer 120 provided on an opposite side to the conductive layer 102 with respect to the plurality of transistor structures 110; and a plurality of capacitor structures 130 provided between the plurality of transistor structures 110 and the conductive layer 102.

As shown in FIG. 3, for example, the transistor structure 110 comprises: a semiconductor layer 111 connected to an outer peripheral surface of the via wiring 104 and extending in the X-direction; an insulating layer 112 provided on an upper surface, a lower surface, both side surfaces in the Y-direction, and a side surface on one side in the X-direction (a conductive layer 120 side) of the semiconductor layer 111; and a conductive layer 113 provided on an upper surface, a lower surface, both side surfaces in the Y-direction, and a side surface on one side in the X-direction (the conductive layer 120 side) of the insulating layer 112.

In an XY cross section of the kind exemplified in FIG. 4, a side surface on one side (a conductive layer 102 side) in the X-direction of the semiconductor layer 111 may be formed along a circle centered on a center position of the via wiring 104. Moreover, side surfaces on the other side (the conductive layer 120 side) in the X-direction of the semiconductor layer 111, insulating layer 112, and conductive layer 113 may be formed linearly along a side surface of the conductive layer 120. Moreover, both side surfaces in the Y-direction of the semiconductor layer 111, insulating layer 112, and conductive layer 113 may be formed linearly along a side surface of an insulating layer 115.

The semiconductor layer 111 functions as a channel region of the transistor TrC (FIG. 1), for example. The semiconductor layer 111 may be, for example, a semiconductor including: at least one element of gallium (Ga) and aluminum (Al); indium (In); zinc (Zn); and oxygen (O), or may be, for example, another oxide semiconductor. A plurality of the semiconductor layers 111 arranged in the Z-direction are commonly connected to the via wiring 104 extending in the Z-direction.

The insulating layer 112 functions as a gate insulating film of the transistor TrC (FIG. 1), for example. The insulating layer 112 includes the likes of silicon oxide (SiO₂), for example.

The conductive layer 113 functions as the gate electrode of the transistor TrC (FIG. 1), for example. The conductive layer 113 includes titanium nitride (TiN) and a conductive oxide such as indium tin oxide (ITO), for example. A plurality of the conductive layers 113 arranged in the Y-direction are commonly connected to the conductive layer 120 extending in the Y-direction (refer to FIG. 2). The conductive layer 113 faces the upper surface, the lower surface, both side surfaces in the Y-direction, and the side surface on one side (the conductive layer 120 side) in the X-direction of the semiconductor layer 111, via the insulating layer 112.

The insulating layer 115 of the likes of silicon oxide (SiO₂) is provided between two of the semiconductor layers 111 adjacent in the Y-direction. The insulating layer 115 extends in the Z-direction penetrating the plurality of memory layers ML.

The conductive layer 120 functions as the word line WL (FIG. 1), for example. The conductive layer 120 extends in the Y-direction, and is connected to a plurality of the conductive layers 113 arranged in the Y-direction. The conductive layer 120 comprises a barrier conductive film 121 of the likes of titanium nitride (TiN) and a conductive film 122 of tungsten (W), for example.

As shown in FIGS. 4 and 5, for example, the capacitor structure 130 comprises: a conductive layer 131; a conductive layer 132 provided on an upper surface, a lower surface, both side surfaces in the Y-direction, and a side surface on one side (a transistor structure 110 side) in the X-direction of the conductive layer 131; an insulating layer 133 provided on an upper surface, a lower surface, both side surfaces in the Y-direction, and a side surface on one side (the transistor structure 110 side) in the X-direction of the conductive layer 132; a conductive layer 134 provided on an upper surface, a lower surface, both side surfaces in the Y-direction, and a side surface on one side (the transistor structure 110 side) in the X-direction of the insulating layer 133; an insulating layer 135 provided on an upper surface, a lower surface, and both side surfaces in the Y-direction of the conductive layer 134; a conductive layer 136 provided on an upper surface, a lower surface, and both side surfaces in the Y-direction of the insulating layer 135; and a conductive layer 137 provided on an upper surface, a lower surface, and both side surfaces in the Y-direction of the conductive layer 136.

The conductive layers 131, 132, 136, 137 function as one electrode of the capacitor CpC (FIG. 1). The conductive layers 131, 137 include the likes of tungsten (W), for example. The conductive layers 132, 136 include the likes of titanium nitride (TiN), for example. The conductive layers 131, 132, 136, 137 are connected to the conductive layer 102.

The insulating layers 133, 135 function as an insulating layer of the capacitor CpC (FIG. 1). The insulating layers 133, 135 may be of zirconia (ZrO₂), alumina (Al₂O₃), or another insulating metal oxide, for example. Moreover, the insulating layers 133, 135 may each be for example a stacked film of a plurality of insulating metal oxides (for example, a stacked film of zirconia and alumina).

The conductive layer 134 functions as the other electrode of the capacitor CpC (FIG. 1), for example. The conductive layer 134 includes a conductive oxide such as indium tin oxide (ITO), for example. The conductive layer 134 is insulated from the conductive layers 131, 132, 136, 137 via the insulating layers 133, 135. The conductive layer 134 is connected to a side surface in the X-direction of the semiconductor layer 111.

### [Method of Manufacturing]

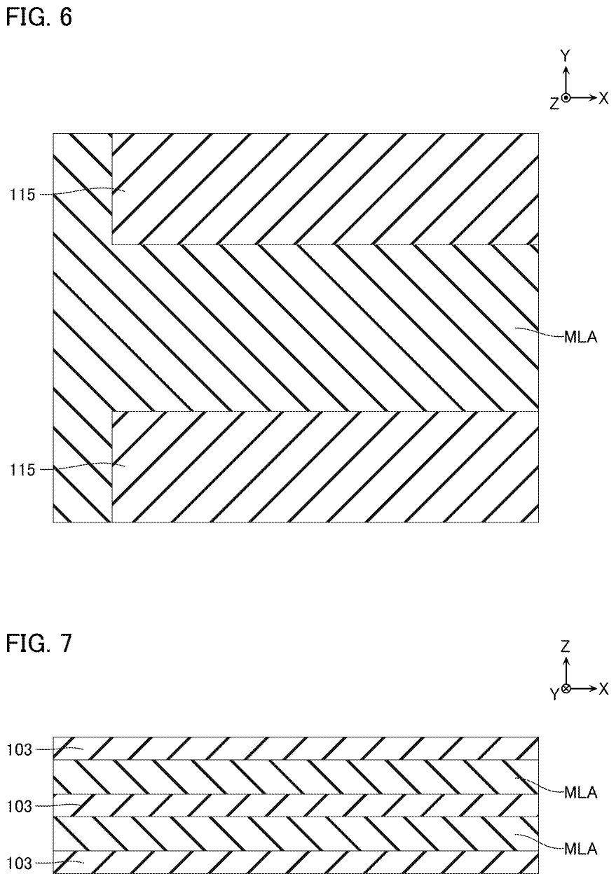

FIGS. 6 to 59 are schematic cross-sectional views for explaining a method of manufacturing the semiconductor memory device according to the first embodiment. FIGS. 6, 8, 10, 12, 14, 16, 18, 20, 22, 24, 26, 28, 30, 32, 34, 36, 38, 40, 42, 44, 46, 48, 50, 52, 54, 56, and 58 show cross sections corresponding to FIG. 4. FIGS. 7, 9, 11, 13, 15, 17, 19, 21, 23, 25, 27, 29, 31, 33, 35, 37, 39, 41, 43, 45, 47, 49, 51, 53, 55, 57, and 59 show cross sections corresponding to FIG. 5.

In the method of manufacturing, as shown in FIG. 7, for example, the plurality of insulating layers 103 and a plurality of sacrifice layers MLA are alternately formed. The sacrifice layer MLA includes the likes of silicon nitride (Si₃N₄), for example. This step is performed by the likes of CVD (Chemical Vapor Deposition), for example.

Next, as shown in FIG. 6, for example, the insulating layer 115 is formed. In this step, for example, an opening is formed at a position corresponding to the insulating layer 115. This opening extends in the Z-direction and penetrates the plurality of insulating layers 103 and the plurality of sacrifice layers MLA arranged in the Z-direction. This step is performed by the likes of RIE (Reactive Ion Etching), for example. After formation of the opening, the insulating layer 115 is formed. This step is performed by the likes of CVD, for example.

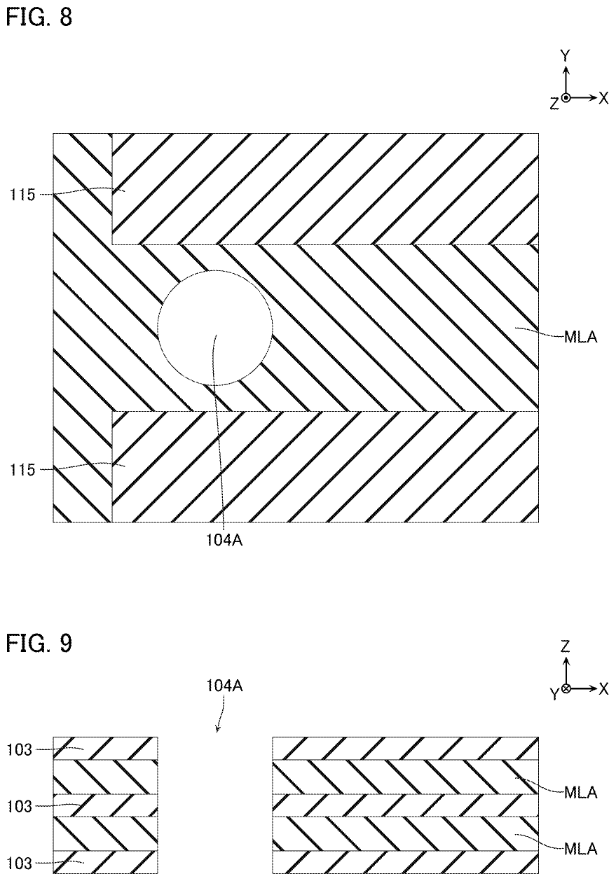

Next, as shown in FIGS. 8 and 9, for example, an opening 104A is formed at a position corresponding to the via wiring 104. The opening 104A extends in the Z-direction and penetrates the plurality of insulating layers 103 and the plurality of sacrifice layers MLA arranged in the Z-direction, as shown in FIG. 9. This step is performed by the likes of RIE, for example. Note that after formation of the opening 104A, an upper portion of the opening 104A is blocked by an insulating layer, or the like, although illustration of this is omitted in the drawings.

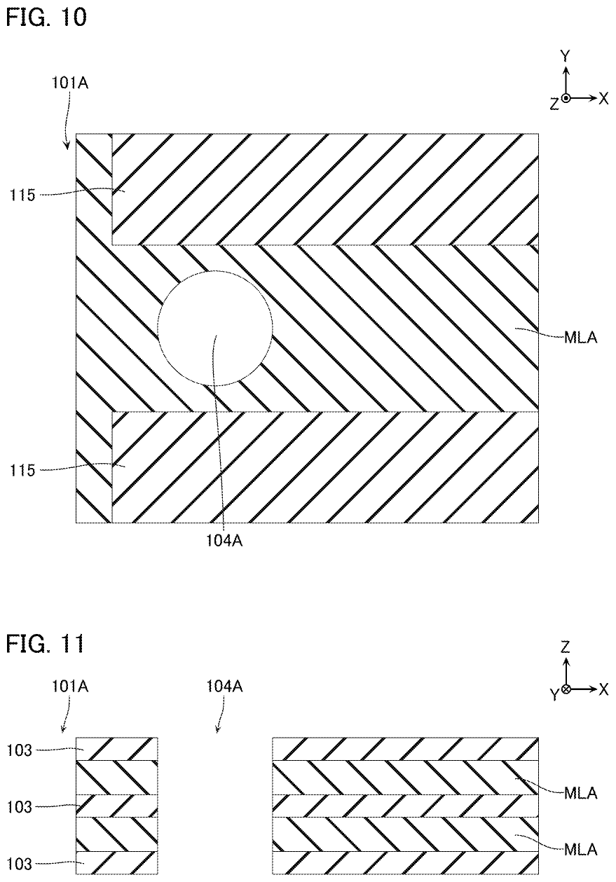

Next, as shown in FIGS. 10 and 11, for example, an opening 101A is formed in a vicinity of a position corresponding to the conductive layer 120. The opening 101A extends in the Y-direction and the Z-direction, and penetrates the plurality of insulating layers 103 and the plurality of sacrifice layers MLA arranged in the Z-direction, to divide these configurations in the X-direction. This step is performed by the likes of RIE, for example.

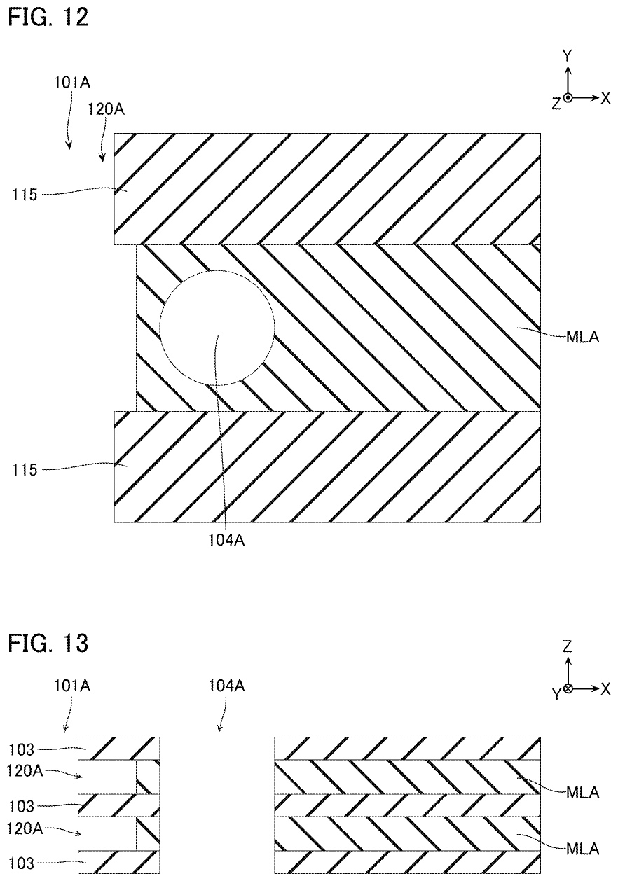

Next, as shown in FIGS. 12 and 13, for example, an opening 120A is formed at the position corresponding to the conductive layer 120. A part of an upper surface and a part of a lower surface of the insulating layer 103, and a part of a side surface in the X-direction of the sacrifice layer MLA are exposed inside the opening 120A. In this step, a part of the sacrifice layer MLA is selectively removed via the opening 101A, for example. This step is performed by the likes of wet etching, for example. Note that the opening 120A does not communicate with the opening 104A.

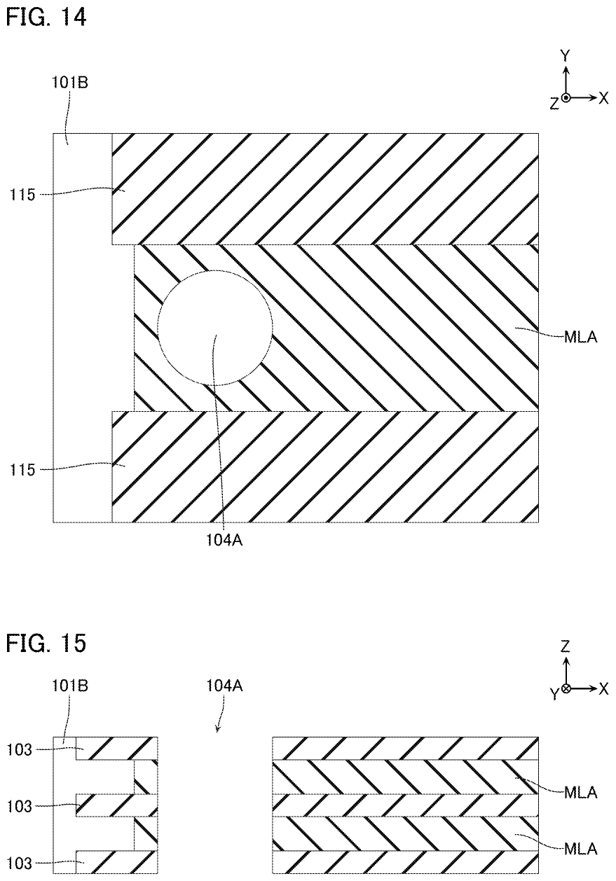

Next, as shown in FIGS. 14 and 15, for example, the opening 101A and the opening 120A are embedded with a sacrifice layer 101B of the likes of silicon (Si). This step is performed by the likes of CVD, for example.

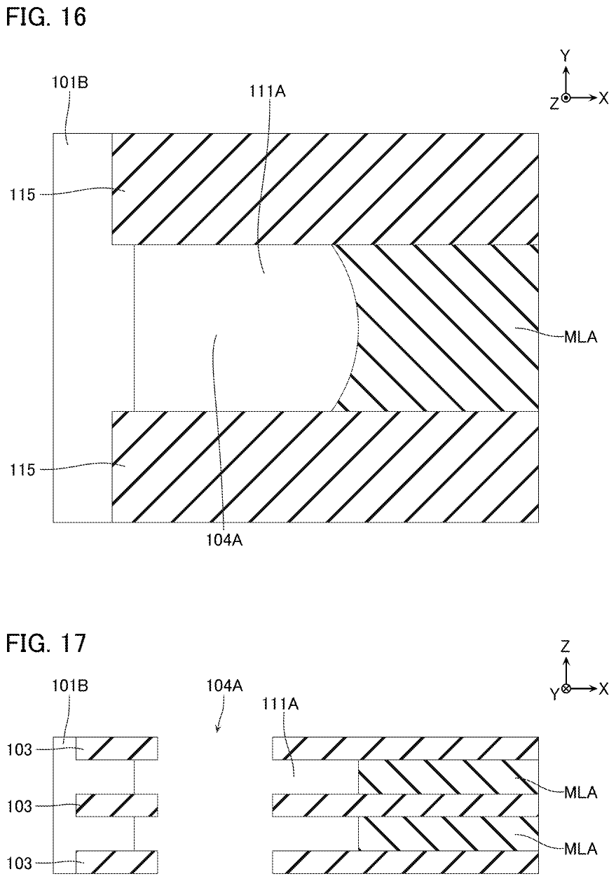

Next, as shown in FIGS. 16 and 17, for example, an opening 111A is formed at a position corresponding to the semiconductor layer 111. A part of the upper surface and a part of the lower surface of the insulating layer 103, a part of the side surface in the X-direction of the sacrifice layer MLA, a part of a side surface in the Y-direction of the insulating layer 115, and a part of a side surface in the X-direction of the sacrifice layer 101B are exposed inside the opening 111A. In this step, a part of the sacrifice layer MLA is selectively removed via the opening 104A, for example. This step is performed by the likes of wet etching, for example.

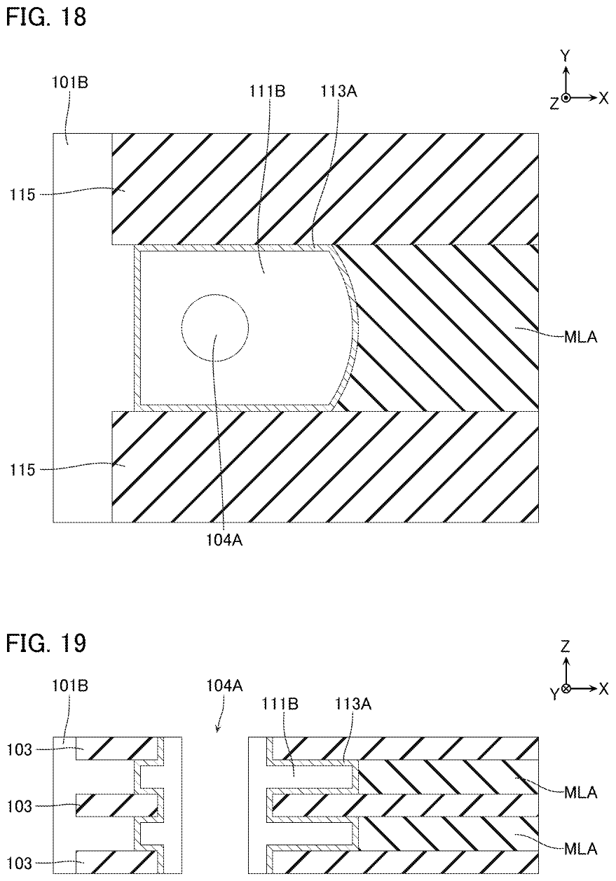

Next, as shown in FIGS. 18 and 19, for example, a conductive layer 113A and a sacrifice layer 111B which is of the likes of silicon (Si) are formed inside the opening 111A and the opening 104A. The conductive layer 113A is formed on a part of the upper surface, a part of the lower surface, and a surface exposed to the opening 104A of the insulating layer 103, a part of the side surface in the X-direction of the sacrifice layer MLA, a part of the side surface in the Y-direction of the insulating layer 115, and a part of the side surface in the X-direction of the sacrifice layer 101B. Moreover, the opening 111A is embedded with the sacrifice layer 111B, but the opening 104A is not embedded with the sacrifice layer 111B. This step is performed by the likes of CVD, for example. Note that after formation of the conductive layer 113A and sacrifice layer 111B, an upper portion of the opening 104A is blocked by an insulating layer, or the like, although illustration of this is omitted in the drawings.

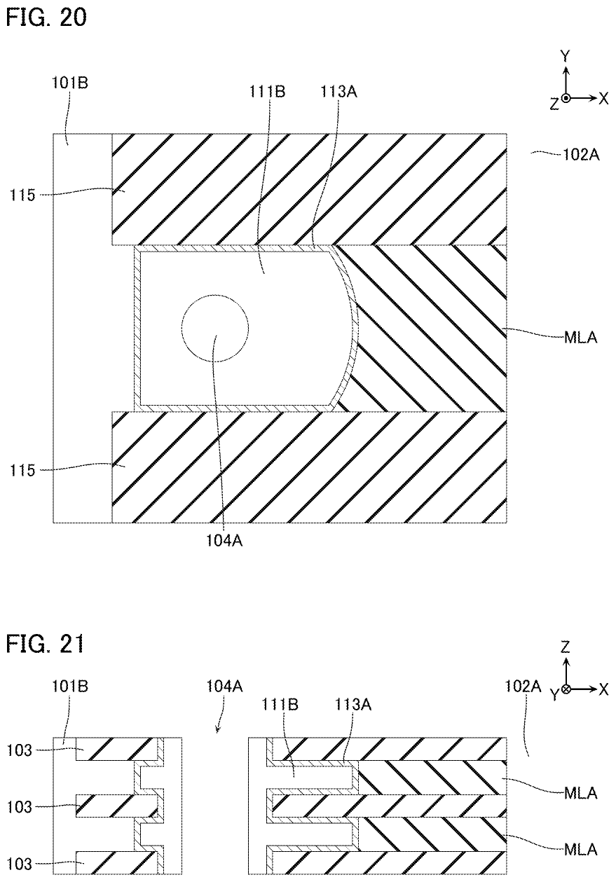

Next, as shown in FIGS. 20 and 21, for example, an opening 102A is formed at a position corresponding to the conductive layer 102. The opening 102A extends in the Y-direction and the Z-direction, and penetrates the plurality of insulating layers 103 and the plurality of sacrifice layers MLA arranged in the Z-direction, and the insulating layer 115, to divide these configurations in the X-direction. This step is performed by the likes of RIE, for example.

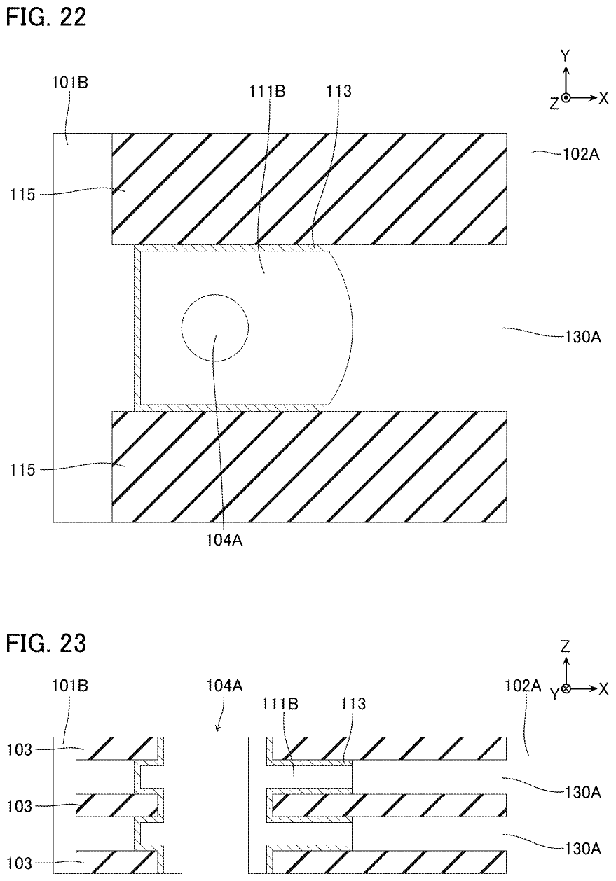

Next, as shown in FIGS. 22 and 23, for example, an opening 130A is formed at a position corresponding to the capacitor structure 130. In this step, the sacrifice layer MLA is removed via the opening 102A. Moreover, a portion covering a side surface on one side (the side surface on an opening 102A side) in the X-direction of the sacrifice layer 111B, of the conductive layer 113A is removed. In this step, the side surface in the X-direction of the sacrifice layer 111B is exposed inside the opening 102A. This step is performed by the likes of wet etching, for example.

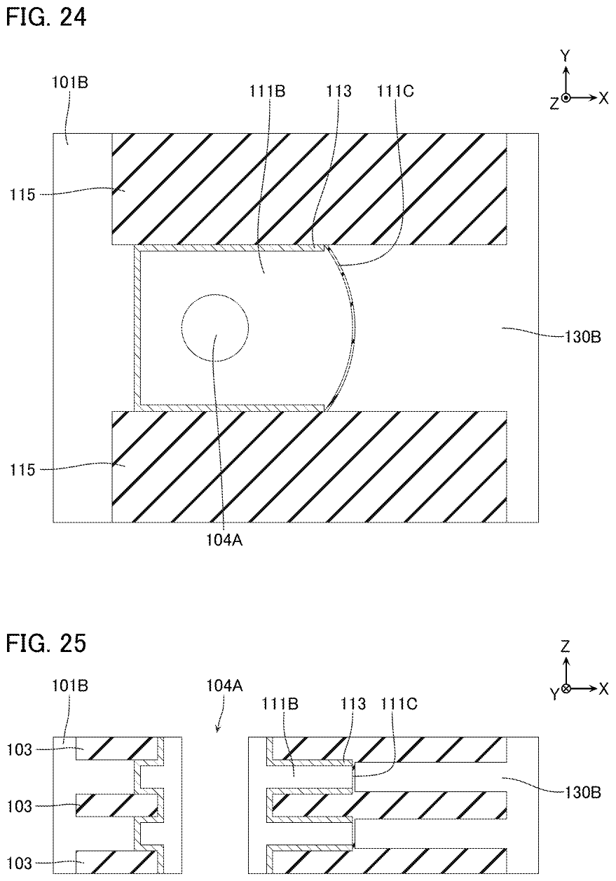

Next, as shown in FIGS. 24 and 25, for example, oxidation process is performed on the sacrifice layer 111B, and an insulating layer 111C is formed, via the opening 102A and the opening 130A. Moreover, the opening 102A and the opening 130A are embedded with a sacrifice layer 130B of the likes of silicon (Si). This step is performed by the likes of CVD, for example.

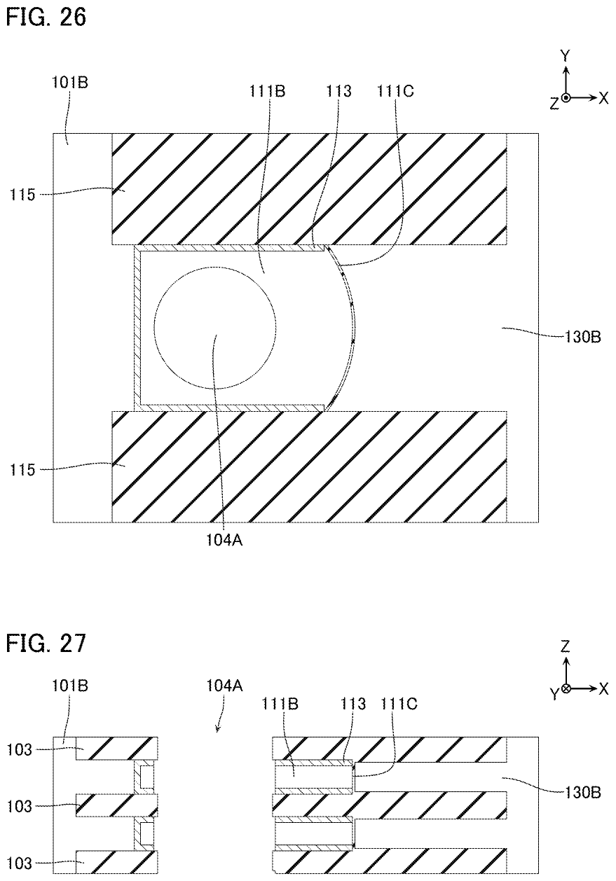

Next, as shown in FIGS. 26 and 27, for example, the conductive layer 113 is formed. In this step, for example, a portion provided on an inner peripheral surface of the opening 104A, of the sacrifice layer 111B is removed. Next, a portion provided on an inner peripheral surface of the opening 104A, of the conductive layer 113A is removed, and the conductive layer 113A is divided in the Z-direction. This step is performed by the likes of wet etching, for example.

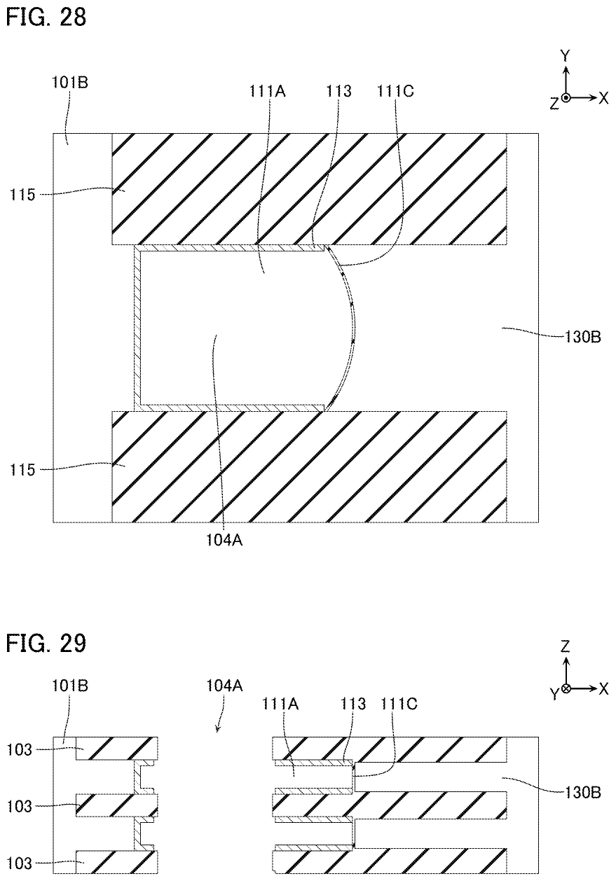

Next, as shown in FIGS. 28 and 29, for example, the sacrifice layer 111B is removed. This step is performed by the likes of wet etching, for example.

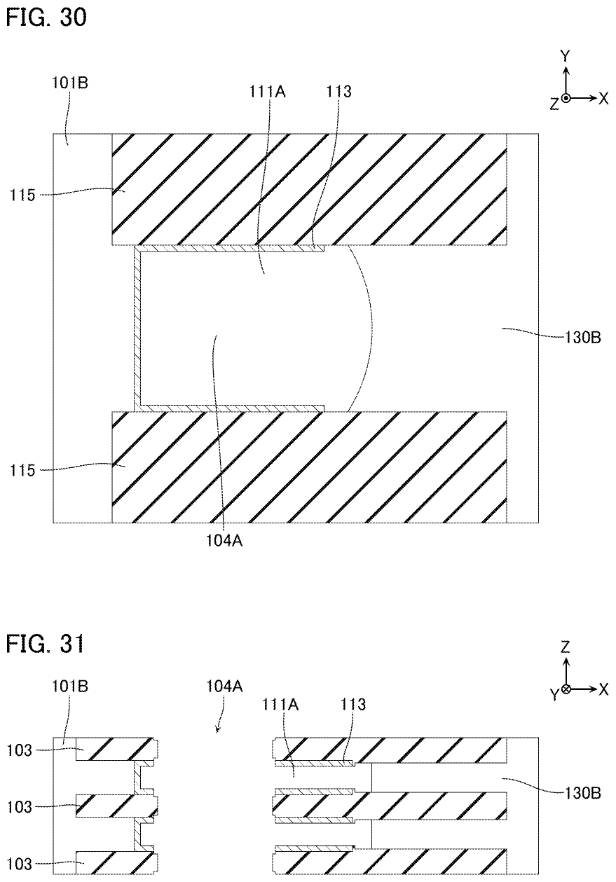

Next, as shown in FIGS. 30 and 31, for example, the insulating layer 111C and a part of the sacrifice layer 130B are removed. This step is performed by the likes of wet etching, for example.

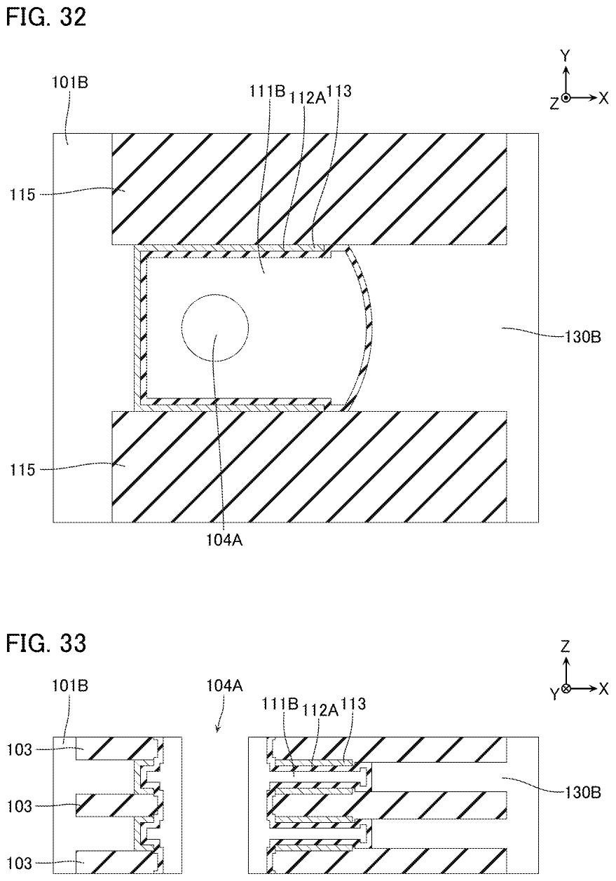

Next, as shown in FIGS. 32 and 33, for example, an insulating layer 112A and the sacrifice layer 111B are formed inside the opening 111A and the opening 104A. The insulating layer 112A is formed on an upper surface, a lower surface, and a surface exposed to the opening 111A of the conductive layer 113, a part of the upper surface, a part of the lower surface, and a surface exposed to the opening 104A of the insulating layer 103, a part of a side surface in the X-direction of the sacrifice layer 130B, and a part of the side surface in the Y-direction of the insulating layer 115. Moreover, the opening 111A is embedded with the sacrifice layer 111B, but the opening 104A is not embedded with the sacrifice layer 111B. This step is performed by the likes of CVD, for example. Note that after formation of the insulating layer 112A and sacrifice layer 111B, an upper portion of the opening 104A is blocked by an insulating layer, or the like, although illustration of this is omitted in the drawings.

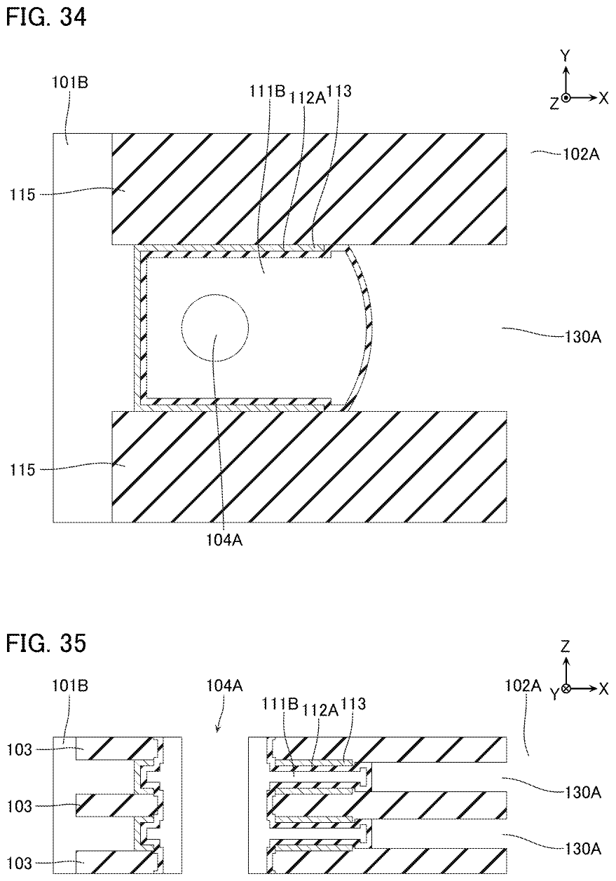

Next, as shown in FIGS. 34 and 35, for example, the sacrifice layer 130B is removed. This step is performed by the likes of wet etching, for example.

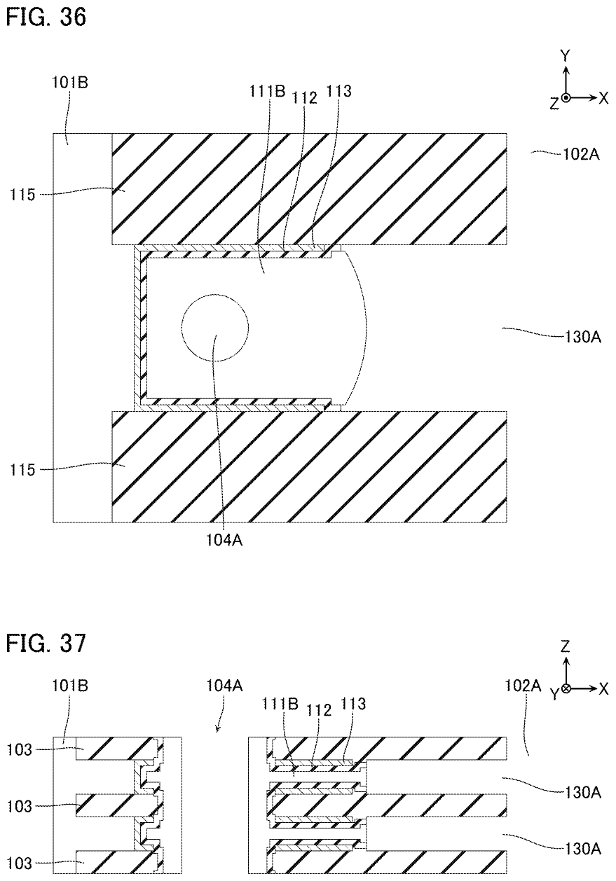

Next, as shown in FIGS. 36 and 37, for example, the insulating layer 112 is formed. In this step, a portion covering a side surface on one side (the side surface on the opening 102A side) in the X-direction of the sacrifice layer 111B, of the insulating layer 112A is removed via the opening 102A and the opening 130A. In this step, the side surface in the X-direction of the sacrifice layer 111B is exposed inside the opening 102A. This step is performed by the likes of wet etching, for example.

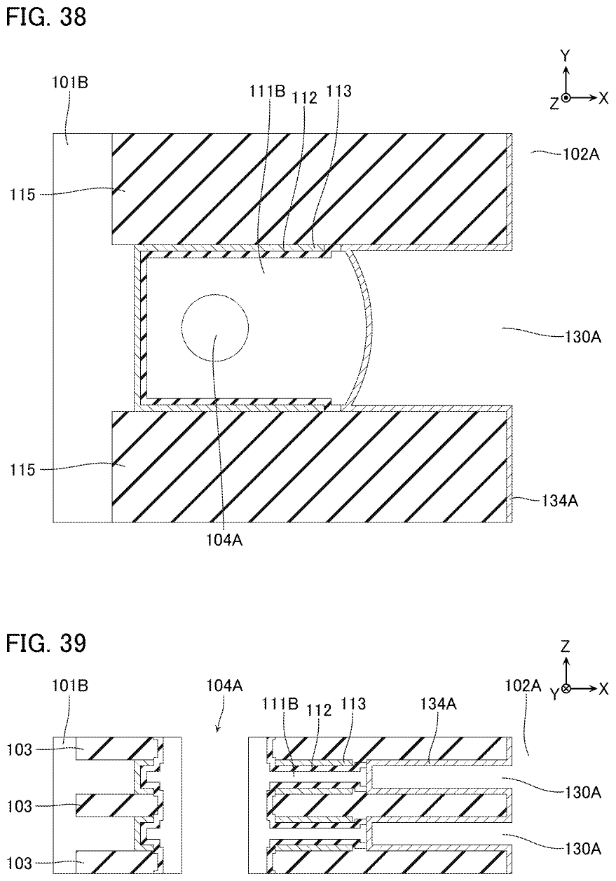

Next, as shown in FIGS. 38 and 39, for example, a conductive layer 134A is formed on a side surface on one side (the side surface on the opening 102A side) in the X-direction of the sacrifice layer 111B, a side surface on one side (the opening 102A side) in the X-direction and both side surfaces in the Y-direction of the insulating layer 115, and the upper surface, the lower surface, and a side surface on one side (the opening 102A side) in the X-direction of the insulating layer 103, via the opening 102A and the opening 130A. This step is performed by the likes of ALD (Atomic Layer Deposition), for example.

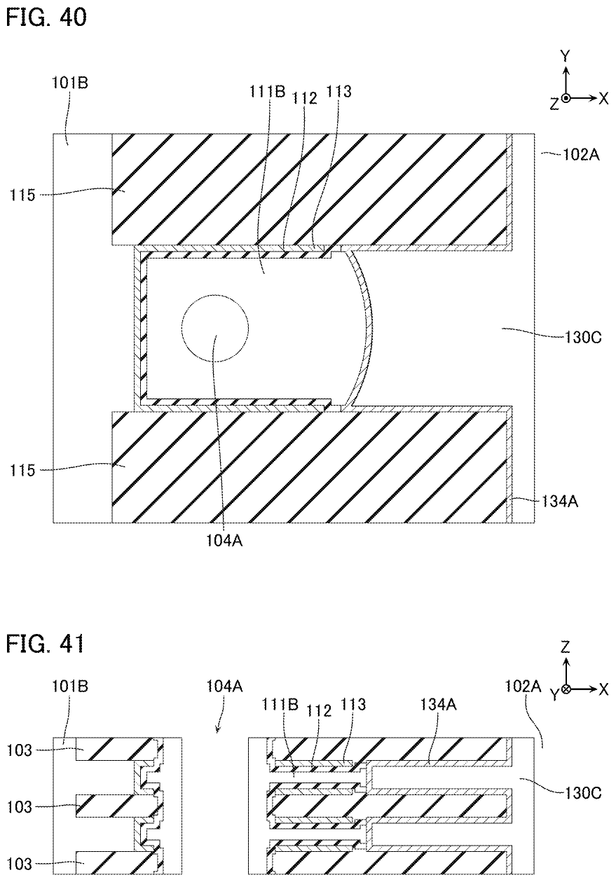

Next, as shown in FIGS. 40 and 41, for example, a sacrifice layer 130C of the likes of silicon (Si) is formed inside the opening 102A. The opening 130A is embedded with the sacrifice layer 130C, but the opening 102A is not embedded with the sacrifice layer 130C. This step is performed by the likes of CVD, for example.

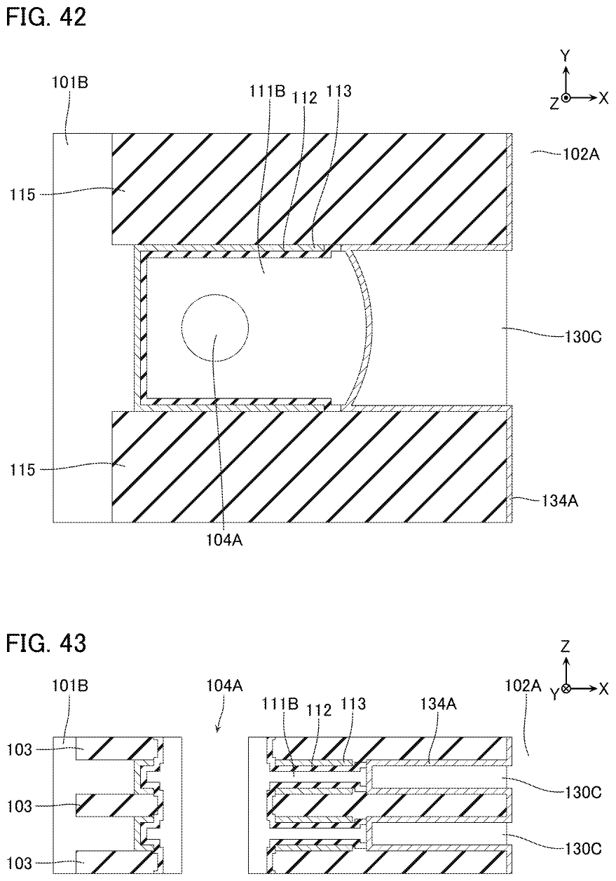

Next, as shown in FIGS. 42 and 43, for example, a part of the sacrifice layer 130C is removed via the opening 102A. In this step, for example, portions provided on side surfaces in the X-direction of the insulating layer 115 and insulating layer 103, of the conductive layer 134A are exposed. This step is performed by the likes of wet etching, for example.

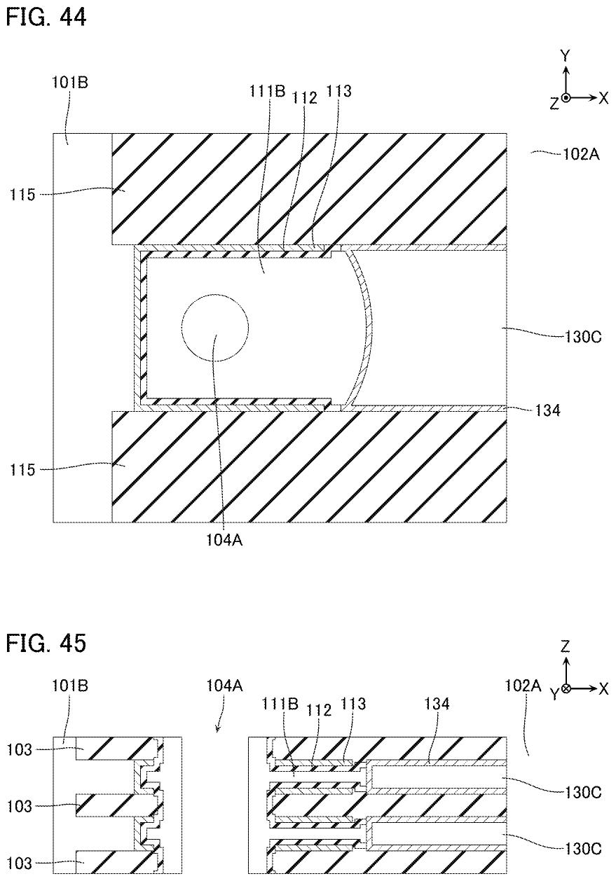

Next, as shown in FIGS. 44 and 45, for example, the conductive layer 134 is formed. In this step, for example, the portions provided on the side surfaces in the X-direction of the insulating layer 115 and insulating layer 103, of the conductive layer 134A are removed, and the conductive layer 134A is divided in the Y-direction and the Z-direction. This step is performed by the likes of wet etching, for example.

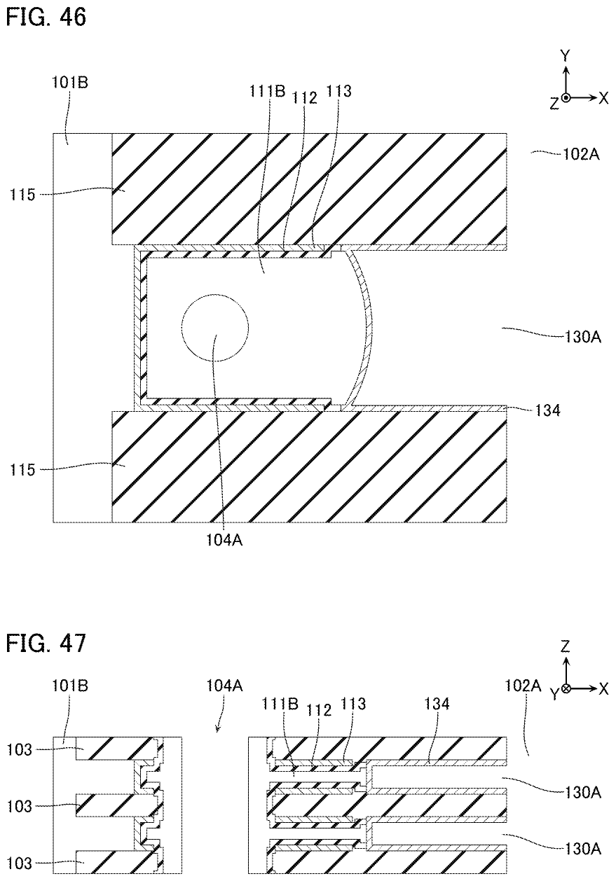

Next, as shown in FIGS. 46 and 47, for example, the sacrifice layer 130C is removed. This step is performed by the likes of wet etching, for example.

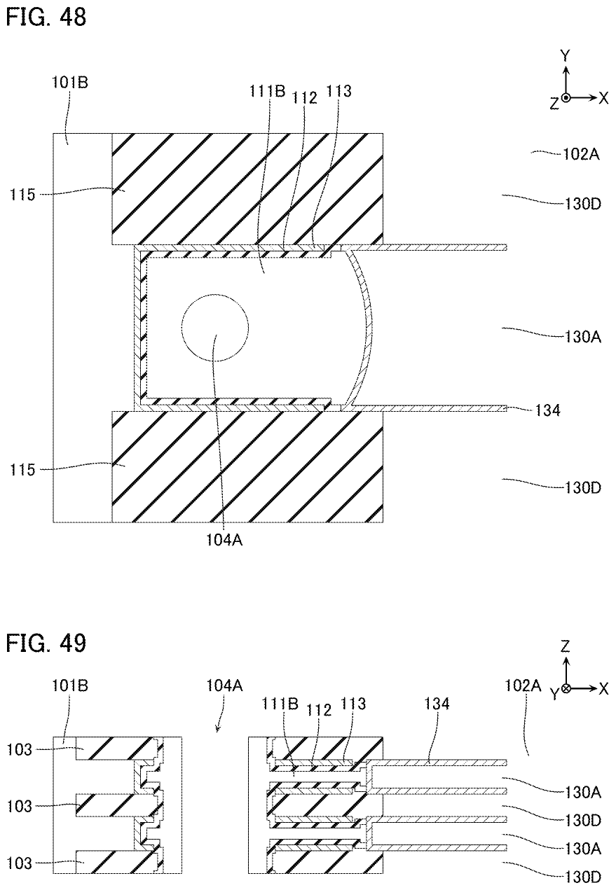

Next, as shown in FIGS. 48 and 49, for example, a part of the insulating layer 115 (FIG. 27) and a part of the insulating layer 103 (FIG. 28) are removed via the opening 102A to form an opening 130D. In the example illustrated, a region on an inner side of the conductive layer 134 is indicated as the opening 130A, and a region on an outer side of the conductive layer 134 is indicated as the opening 130D. In this step, the insulating layer 115 (FIG. 27) and insulating layer 103 (FIG. 28) are removed in a range limited enough to prevent the conductive layer 113 from being exposed in the opening 130D. This step is performed by the likes of wet etching, for example.

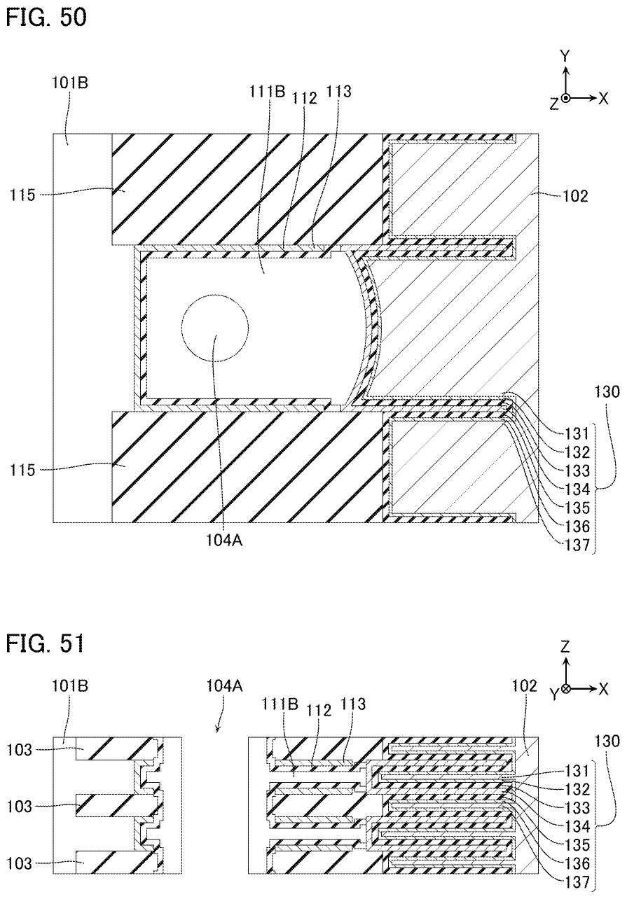

Next, as shown in FIGS. 50 and 51, for example, the insulating layers 133, 135, the conductive layers 132, 136, and the conductive layers 131, 137, 102 are formed on an upper surface, a lower surface, a side surface on one side (the side surface on the opening 102A side) in the X-direction, and both side surfaces in the Y-direction of the conductive layer 134, via the opening 130A, the opening 130D, and the opening 102A. This step is performed by the likes of CVD, for example.

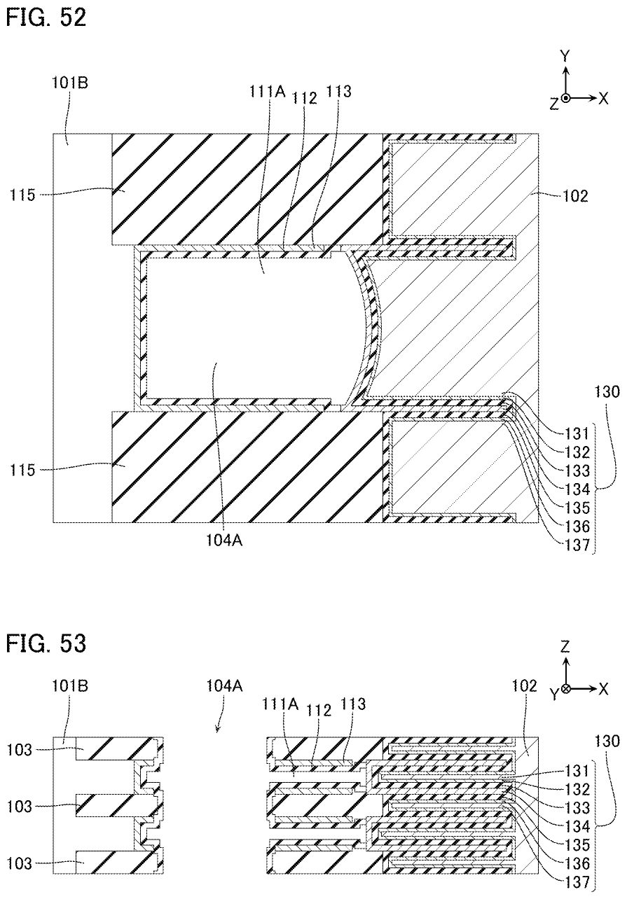

Next, as shown in FIGS. 52 and 53, for example, the sacrifice layer 111B is removed. This step is performed by the likes of wet etching, for example.

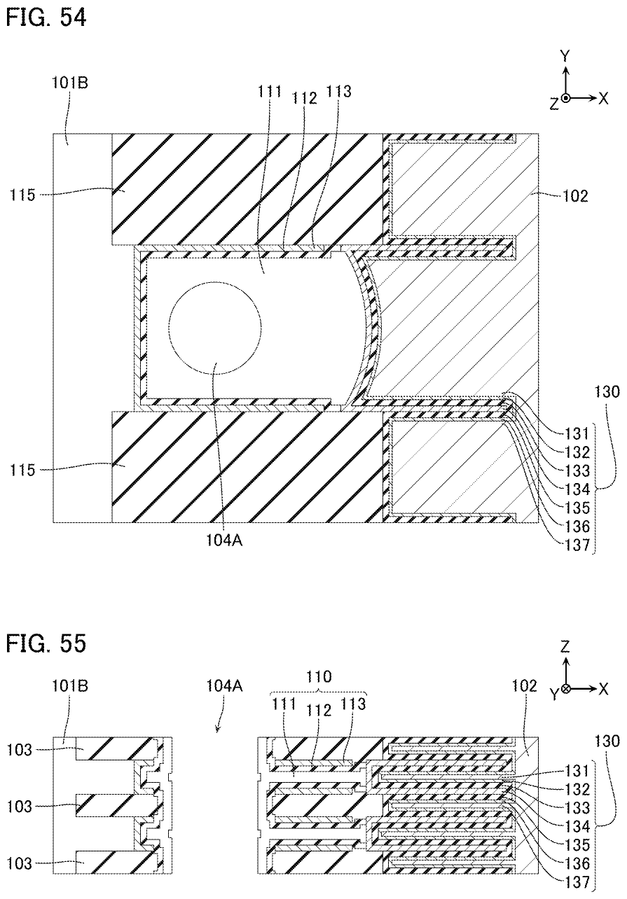

Next, as shown in FIGS. 54 and 55, for example, the semiconductor layer 111 is formed inside the opening 111A and the opening 104A. The opening 111A is embedded with the semiconductor layer 111. The opening 104A is not embedded with the semiconductor layer 111. This step is performed by the likes of ALD, for example.

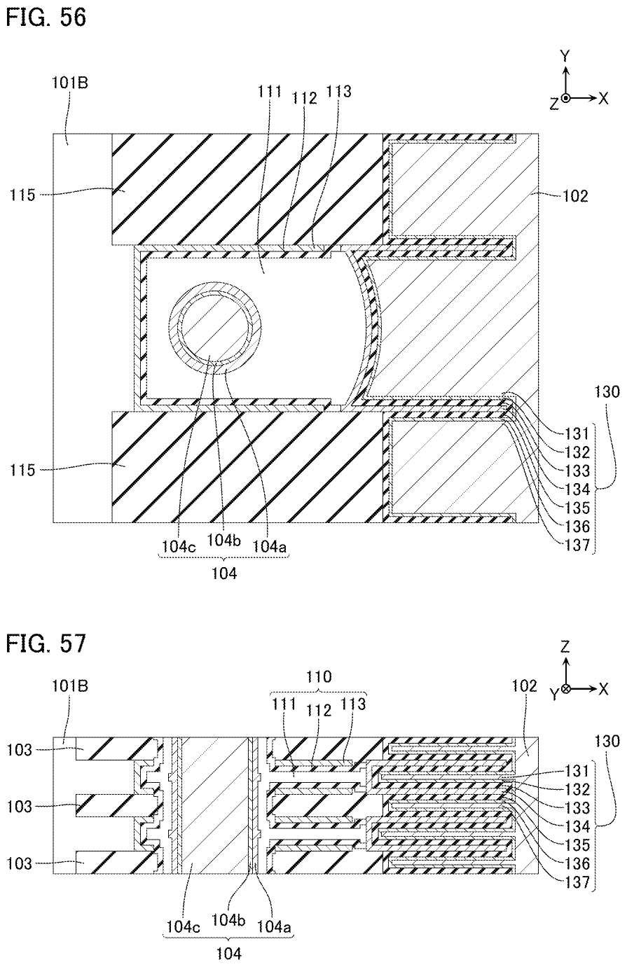

Next, as shown in FIGS. 56 and 57, for example, the via wiring 104 is formed inside the opening 104A. This step is performed by the likes of ALD and CVD, for example.

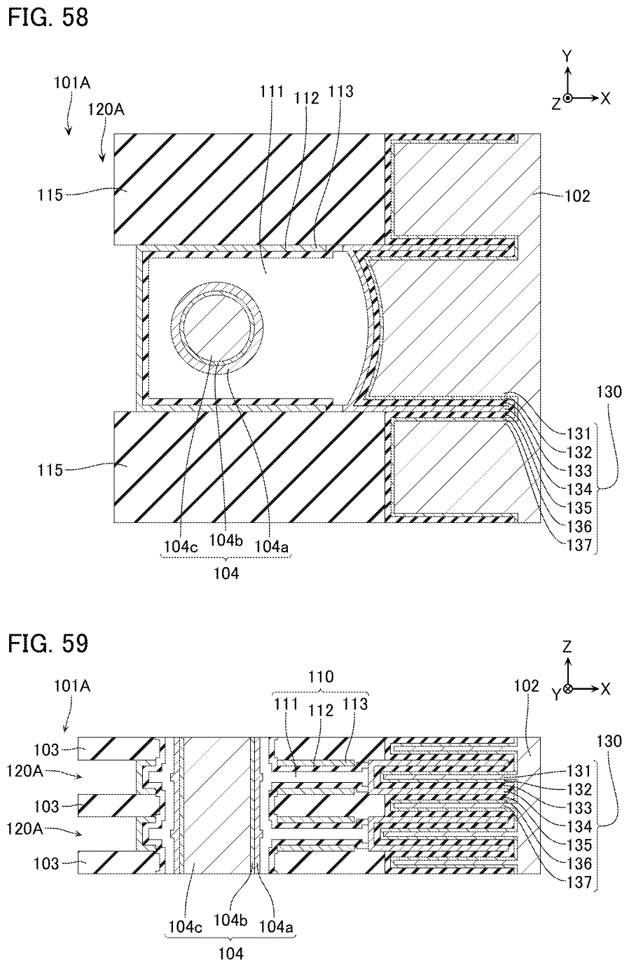

Next, as shown in FIGS. 58 and 59, for example, the sacrifice layer 101B is removed. This step is performed by the likes of wet etching, for example.

Subsequently, as shown in FIGS. 4 and 5, for example, the conductive layer 120 is formed inside the opening 120A. This step is performed by the likes of CVD, for example.

### [Advantages]

The semiconductor memory device according to the present embodiment comprises: the plurality of memory layers ML arranged in the Z-direction; and the via wiring 104 extending in the Z-direction. Moreover, the plurality of memory layers ML each comprise: the transistor structure 110; the capacitor structure 130 provided on one side in the X-direction with respect to the transistor structure 110; and the conductive layer 120 provided on the other side in the X-direction with respect to the transistor structure 110.

Even when the number of memory layers ML included in the memory cell array MCA has increased, this kind of configuration can be manufactured without the number of steps being increased other than in a laminating step (the step described with reference to FIG. 7). Hence, a rise in degree-of-integration can be comparatively easily achieved.

Moreover, in the transistor structure 110 according to the present embodiment, the conductive layer 113 faces the upper surface, the lower surface, and both side surfaces in the Y-direction of the semiconductor layer 111.

In this kind of configuration, it is possible for interference of electric fields occurring between a plurality of the semiconductor layers 111 arranged in the Z-direction to be suppressed. Hence, even when a rise in degree-of-integration in the Z-direction of the memory cell array MCA has been achieved, it is possible for the semiconductor layer 111 to be suitably controlled to an ON state or an OFF state, and possible for a suitably-operating semiconductor memory device to be provided.

Moreover, when the transistor TrC is set to an ON state, a channel is formed in the upper surface, the lower surface, and both side surfaces in the Y-direction of the semiconductor layer 111. Hence, it is possible for an ON current of the transistor TrC to be made comparatively large. This enables speeding-up and stability of operation to be achieved.

Now, it is conceivable too for a wiring functioning as the word line WL (a wiring extending in the Y-direction) to be provided between the via wiring 104 and the capacitor structure 130, and for a part of this wiring functioning as the word line WL to be utilized as the gate electrode of the transistor TrC, for example. However, this kind of structure will resultantly be a structure where the semiconductor layer functioning as the channel region of the transistor TrC and the wiring functioning as the word line WL will intersect viewed from the Z-direction. Hence, for example, it is necessary to process a wiring extending in the Y-direction, without the semiconductor layer being divided in the X-direction, for which degree-of-difficulty of manufacturing is high. Moreover, a width in the Z-direction of the memory layer increases.

In this respect, in the present embodiment, the conductive layer 120 functioning as the word line WL is provided on an opposite side to the plate line PL with respect to the transistor structure 110, and is provided at a position not overlapping the transistor structure 110 viewed from the Z-direction. Hence, it is possible for the conductive layer 120 and the transistor structure 110 to be formed independently, and possible for manufacturing to be performed comparatively easily. Moreover, it is possible for wiring resistance of the conductive layer 120 to be set to a comparatively small value while a width in the Z-direction of the memory layer ML is suppressed.

### Second Embodiment

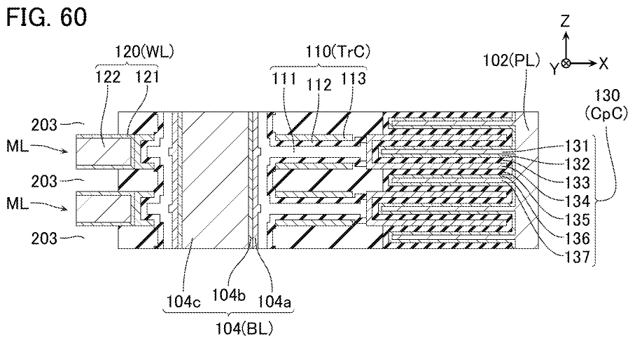

Next, a semiconductor memory device according to a second embodiment will be described with reference to FIG. 60. FIG. 60 is a schematic cross-sectional view showing a part of a configuration of the semiconductor memory device. In the following description, configurations similar to in the first embodiment will be assigned with the same symbols as in the first embodiment, and descriptions thereof omitted.

The semiconductor memory device according to the second embodiment is basically configured similarly to the semiconductor memory device according to the first embodiment.

However, in the second embodiment, a gap 203 is provided between the plurality of conductive layers 120 arranged in the Z-direction. This kind of configuration makes it possible for parasitic capacitance in-between the plurality of conductive layers 120 arranged in the Z-direction to be reduced. As a result, speeding-up of operation can be achieved.

Note that the semiconductor memory device according to the second embodiment is basically manufacturable similarly to the semiconductor memory device according to the first embodiment. However, during manufacturing of the semiconductor memory device according to the second embodiment, subsequent to the step described with reference to FIGS. 58 and 59 having been executed, and the conductive layer 120 having been formed, a part of the insulating layer 103 is removed via the opening 101A. This step is performed by the likes of wet etching, for example.

### Third Embodiment

### [Structure]

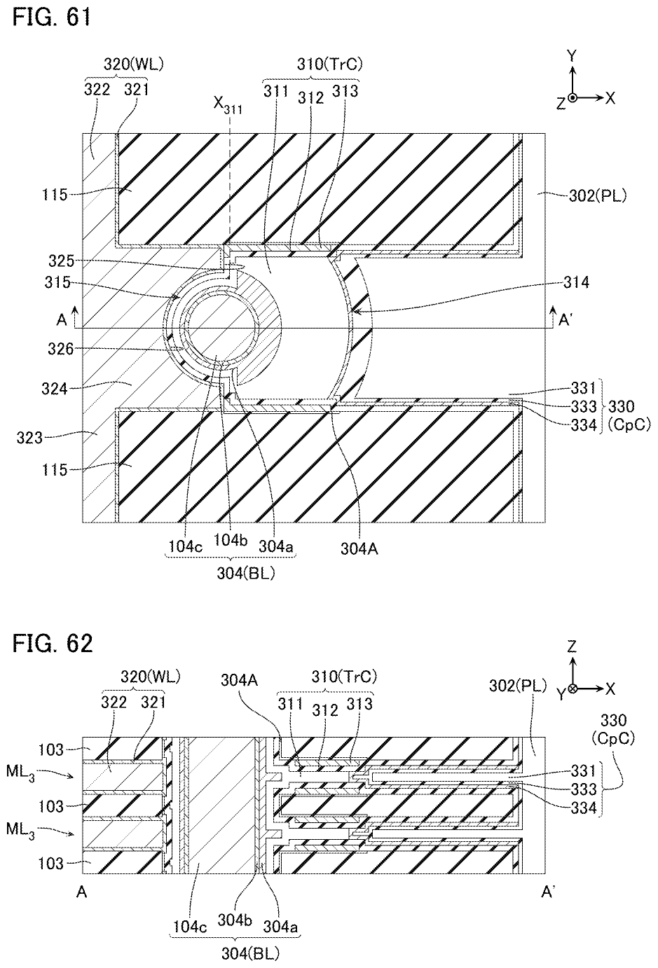

Next, configurations of a semiconductor memory device according to a third embodiment will be described with reference to FIGS. 61 and 62. FIG. 61 is a schematic XY cross-sectional view showing a part of a configuration of the semiconductor memory device. FIG. 62 is a schematic cross-sectional view showing a part of a configuration of the semiconductor memory device, and shows configurations when the structure shown in FIG. 61 has been cut along the line A-A′ and viewed along a direction of the arrows. In the following description, configurations similar to in the first embodiment will be assigned with the same symbols as in the first embodiment, and descriptions thereof omitted.

The semiconductor memory device according to the third embodiment is basically configured similarly to the semiconductor memory device according to the first embodiment.

However, the semiconductor memory device according to the third embodiment comprises a memory layer ML₃ instead of the memory layer ML.

Moreover, the semiconductor memory device according to the third embodiment comprises a conductive layer 302 instead of the conductive layer 102. The conductive layer 302 extends in the Y-direction and the Z-direction, and divides the memory layer ML₃ in the X-direction.

The conductive layer 302 includes the likes of a stacked structure of titanium nitride (TiN) and silicon germanium (SiGe), for example. The conductive layer 302 functions as the plate line PL (FIG. 1), for example.

Moreover, the semiconductor memory device according to the third embodiment comprises a plurality of via wirings 304 instead of the plurality of via wirings 104. The plurality of via wirings 304 are arranged in the Y-direction and extend in the Z-direction penetrating the plurality of memory layers ML₃.

As shown in FIG. 62, the via wiring 304 includes, for example: a conductive oxide film 304a that includes a conductive oxide; the above-mentioned barrier conductive film 104b; and the above-mentioned conductive member 104c. The conductive oxide film 304a comprises: a substantially cylindrically-shaped portion extending in the Z-direction along the outer peripheral surface of the barrier conductive film 104b; and projections that are provided correspondingly to each of the memory layers ML₃ and project to one side (a conductive layer 302 side) in the X-direction. In an XY cross section of the kind exemplified in FIG. 61, a side surface on one side (the conductive layer 302 side) in the X-direction of this projection may be formed along a circle centered on a center position of the via wiring 304. The via wiring 304 functions as the bit line BL (FIG. 1), for example.

The memory layer ML₃ comprises: a plurality of transistor structures 310 provided correspondingly to the plurality of via wirings 304; a conductive layer 320 provided on an opposite side to the conductive layer 302 with respect to the plurality of transistor structures 310; and a plurality of capacitor structures 330 provided between the plurality of transistor structures 310 and the conductive layer 302.

The transistor structure 310 comprises: a semiconductor layer 311 connected to an outer peripheral surface of the via wiring 304 and extending in the X-direction; an insulating layer 312 provided on an upper surface, a lower surface, both side surfaces in the Y-direction, and a side surface on one side (a conductive layer 320 side) in the X-direction of the semiconductor layer 311; and a conductive layer 313 provided on an upper surface, a lower surface, and both side surfaces in the Y-direction of the insulating layer 312.

In the XY cross section of the kind exemplified in FIG. 61, the semiconductor layer 311 comprises: a portion 314 provided further to one side (the conductive layer 302 side) in the X-direction than a position X₃₁₁ in the X-direction; and a portion 315 provided further to the other side (the conductive layer 320 side) in the X-direction than the position X₃₁₁ in the X-direction. In the XY cross section of the kind exemplified in FIG. 61, a cross-sectional area of the portion 315 is smaller than a cross-sectional area of the portion 314.

The position X₃₁₁ is provided between a position of an end portion on one side in the X-direction of the via wiring 304 and a position of an end portion on the other side in the X-direction of the via wiring 304.

A width in the Y-direction of the portion 314 is substantially constant. That is, both side surfaces in the Y-direction of the portion 314 extend in the X-direction along the side surfaces of the insulating layers 115. A side surface on one side (the conductive layer 302 side) in the X-direction of the portion 314 may be formed along a circle centered on the center position of the via wiring 304. A side surface on the other side (the conductive layer 320 side) in the X-direction of the portion 314 extends in the Y-direction.

An outer peripheral surface of the portion 315 is formed along a circle centered on the center position of the via wiring 304.

The insulating layer 312 is formed along both side surfaces in the Y-direction and the side surface on the other side (the conductive layer 320 side) in the X-direction of the portion 314, and the outer peripheral surface of the portion 315.

Moreover, the conductive layer 313 is formed along both side surfaces in the Y-direction of the portion 314. Note that in the example illustrated, a position in the X-direction of an end portion on the other side (the conductive layer 320 side) in the X-direction of the conductive layer 313 is provided between the position X₃₁₁ and a position of an end portion on the other side in the X-direction of the via wiring 304.

The semiconductor layer 311 functions as the channel region of the transistor TrC (FIG. 1), for example. The semiconductor layer 311 may be, for example, a semiconductor including: at least one element of gallium (Ga) and aluminum (Al); indium (In); zinc (Zn); and oxygen (O), or may be, for example, another oxide semiconductor. A plurality of the semiconductor layers 311 arranged in the Z-direction are commonly connected to the via wiring 304 extending in the Z-direction.

The insulating layer 312 functions as the gate insulating film of the transistor TrC (FIG. 1), for example. The insulating layer 312 includes the likes of silicon oxide (SiO₂), for example.

The conductive layer 313 functions as the gate electrode of the transistor TrC (FIG. 1), for example. The conductive layer 313 includes titanium nitride (TiN) and a conductive oxide such as indium tin oxide (ITO), for example. A plurality of the conductive layers 313 arranged in the Y-direction are commonly connected to the conductive layer 320 extending in the Y-direction. The conductive layer 313 faces the upper surface, the lower surface, and both side surfaces in the Y-direction of the semiconductor layer 311, via the insulating layer 312.

The insulating layer 115 of the likes of silicon oxide (SiO₂) is provided between two of the semiconductor layers 311 adjacent in the Y-direction. The insulating layer 115 extends in the Z-direction penetrating the plurality of memory layers ML₃.

The conductive layer 320 functions as the word line WL (FIG. 1), for example. The conductive layer 320 comprises a barrier conductive film 321 of the likes of titanium nitride (TiN) and a conductive film 322 of tungsten (W), for example. The conductive layer 320 comprises: a portion 323 extending in the Y-direction; and a plurality of portions 324 provided correspondingly to a plurality of the transistor structures 310 arranged in the Y-direction. The portions 324 each project to one side (the conductive layer 302 side) in the X-direction, and are connected to the conductive layer 313.

Note that in the XY cross section of the kind exemplified in FIG. 61, a side surface on one side (the conductive layer 302 side) in the X-direction of the portion 324 comprises: two portions 325 that extend in the Y-direction, and are separated in the Y-direction; and a portion 326 which is provided between these two portions 325, and is formed along a circle centered on the center position of the via wiring 304. Moreover, positions in the X-direction of the two portions 325 are provided between the position X₃₁₁ and the position of the end portion on the other side (the conductive layer 320 side) in the X-direction of the via wiring 304. Moreover, both side surfaces in the Y-direction of the portion 324 extend in the X-direction along the side surfaces of the insulating layers 115.

The capacitor structure 330 comprises: a conductive layer 331; an insulating layer 333 provided on an upper surface, a lower surface, both side surfaces in the Y-direction, and a side surface on one side (a transistor structure 310 side) in the X-direction of the conductive layer 331; and a conductive layer 334 provided on an upper surface, a lower surface, both side surfaces in the Y-direction, and a side surface on one side (the transistor structure 310 side) in the X-direction of the insulating layer 333.

The conductive layer 331 functions as one electrode of the capacitor CpC (FIG. 1). The conductive layer 331 includes the likes of a stacked structure of titanium nitride (TiN) and silicon germanium (SiGe), for example. The conductive layer 331 is connected to the conductive layer 302.

The insulating layer 333 function as the insulating layer of the capacitor CpC (FIG. 1). The insulating layer 333 may be of zirconia (ZrO₂), alumina (Al₂O₃), or another insulating metal oxide, for example. Moreover, the insulating layer 333 may be for example a stacked film of a plurality of insulating metal oxides (for example, a stacked film of zirconia and alumina).

The conductive layer 334 functions as the other electrode of the capacitor CpC (FIG. 1), for example. The conductive layer 334 includes a conductive oxide such as indium tin oxide (ITO), for example. The conductive layer 334 is insulated from the conductive layer 331 via the insulating layer 333. The conductive layer 334 is connected to a side surface in the X-direction of the semiconductor layer 311.

### [Advantages]

Areas in an XY cross section of the semiconductor layer 311 and the conductive layer 313 according to the third embodiment are smaller than areas in an XY cross section of the semiconductor layer 111 and the conductive layer 113 according to the first embodiment.

That is, in the semiconductor memory device according to the first embodiment, as exemplified in FIG. 4, both side surfaces in the Y-direction of the semiconductor layer 111 extend in the X-direction along the insulating layers 115, and a width in the Y-direction of the semiconductor layer 111 is substantially constant from one end to the other end in the X-direction of the semiconductor layer 111. Moreover, the conductive layer 113 faces the upper surface, the lower surface, both side surfaces in the Y-direction and the side surface on one side (the conductive layer 120 side) in the X-direction of the semiconductor layer 111, via the insulating layer 112.

On the other hand, in the semiconductor memory device according to the third embodiment, as described with reference to FIG. 61, the semiconductor layer 311 comprises: the portion 314 provided further to one side (the conductive layer 302 side) in the X-direction than the position X₃₁₁; and the portion 315 provided further to the other side (the conductive layer 320 side) in the X-direction than the position X₃₁₁. Moreover, in the XY cross section exemplified in FIG. 61, the cross-sectional area of the portion 315 is smaller than the cross-sectional area of the portion 314. Moreover, the position in the X-direction of the end portion on the other side (the conductive layer 320 side) in the X-direction of the conductive layer 313 is provided between the position X₃₁₁ and the position of the end portion on the other side in the X-direction of the via wiring 304.

Now, during a read operation and a write operation of the semiconductor memory device, a voltage of one of a plurality of the word lines WL (FIG. 1) arranged in the Z-direction is raised from an L state to an H state, whereby the plurality of transistors TrC connected to this word line WL are set to an ON state. At this time, the word line WL is capacitively coupled to the channel regions of the plurality of transistors TrC, via the gate electrodes of the plurality of transistors TrC. Hence, when electrostatic capacitance between the gate electrode and channel region of the transistor TrC is small, it better enables a voltage of the word line WL to be controlled at high speed.

In this respect, the semiconductor memory device according to the third embodiment enables electrostatic capacitance between the gate electrode (conductive layer 313) and the channel region (semiconductor layer 311) of the transistor TrC to be significantly reduced, and thereby enables a semiconductor memory device operating at high speed to be achieved.

### [Method of Manufacturing]

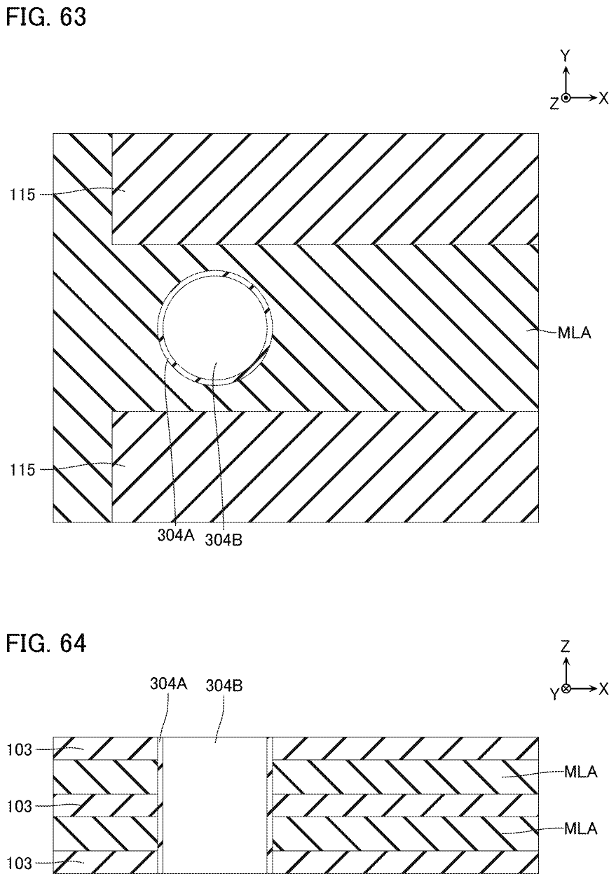

FIGS. 63 to 111 are schematic cross-sectional views for explaining a method of manufacturing the semiconductor memory device according to the third embodiment. FIGS. 63, 65, 67, 69, 71, 74, 76, 78, 80, 82, 84, 86, 88, 90, 92, 94, 96, 98, 100, 102, 104, 106, 108, and 110 show cross sections corresponding to FIG. 61. FIGS. 64, 66, 68, 70, 72, 73, 75, 77, 79, 81, 83, 85, 87, 89, 91, 93, 95, 97, 99, 101, 103, 105, 107, 109, and 111 show cross sections corresponding to FIG. 62.

In the method of manufacturing, for example, the step described with reference to FIG. 7, the step described with reference to FIG. 6, and the step described with reference to FIGS. 8 and 9, are executed. However, after execution of the step described with reference to FIGS. 8 and 9, an upper portion of the opening 104A is not blocked by an insulating layer, or the like.

Next, as shown in FIGS. 63 and 64, for example, a sacrifice film 304A of the likes of silicon oxide (SiO₂) and a sacrifice layer 304B of the likes of silicon (Si) are formed inside the opening 104A. The opening 104A is embedded with the sacrifice layer 304B. This step is performed by the likes of CVD, for example.

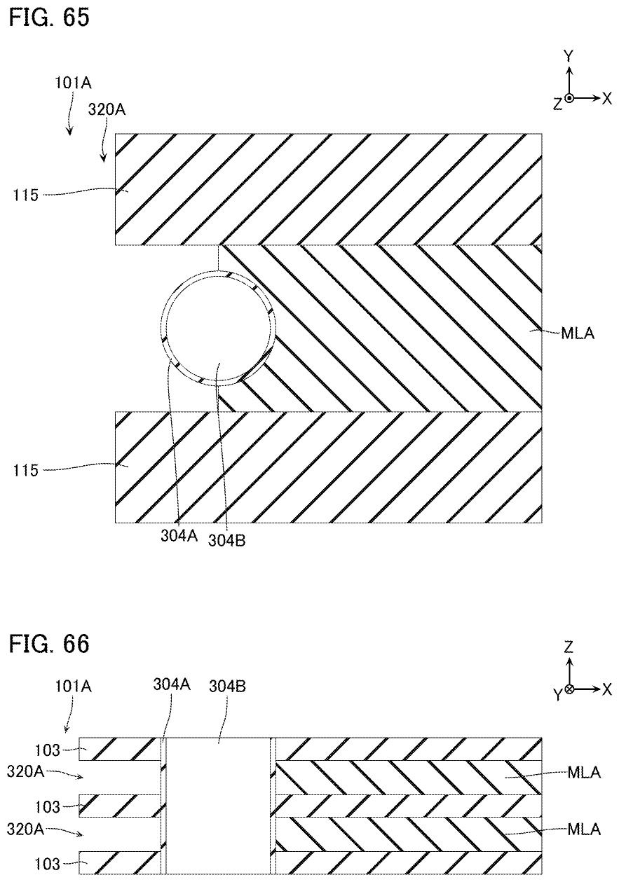

Next, as shown in FIGS. 65 and 66, for example, the opening 101A is formed in a vicinity of a position corresponding to the conductive layer 320. Moreover, an opening 320A is formed at the position corresponding to the conductive layer 320. A part of the upper surface and a part of the lower surface of the insulating layer 103, a part of the side surface in the X-direction of the sacrifice layer MLA, and a part of an outer peripheral surface of the sacrifice film 304A are exposed inside the opening 320A. In this step, a part of the sacrifice layer MLA is selectively removed via the opening 101A, for example. This step is performed by the likes of wet etching, for example.

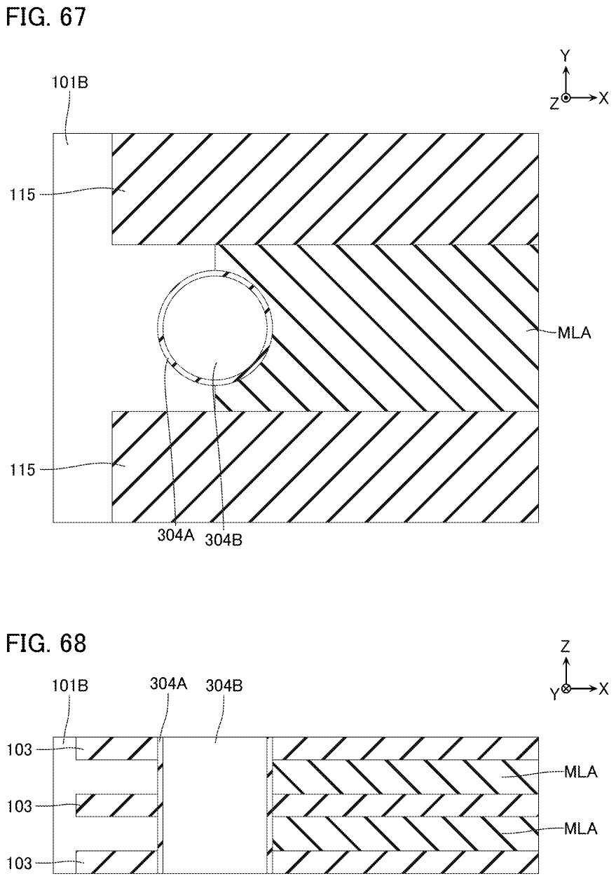

Next, as shown in FIGS. 67 and 68, for example, the opening 101A and the opening 320A are embedded with the sacrifice layer 101B of the likes of silicon (Si). This step is performed by the likes of CVD, for example.

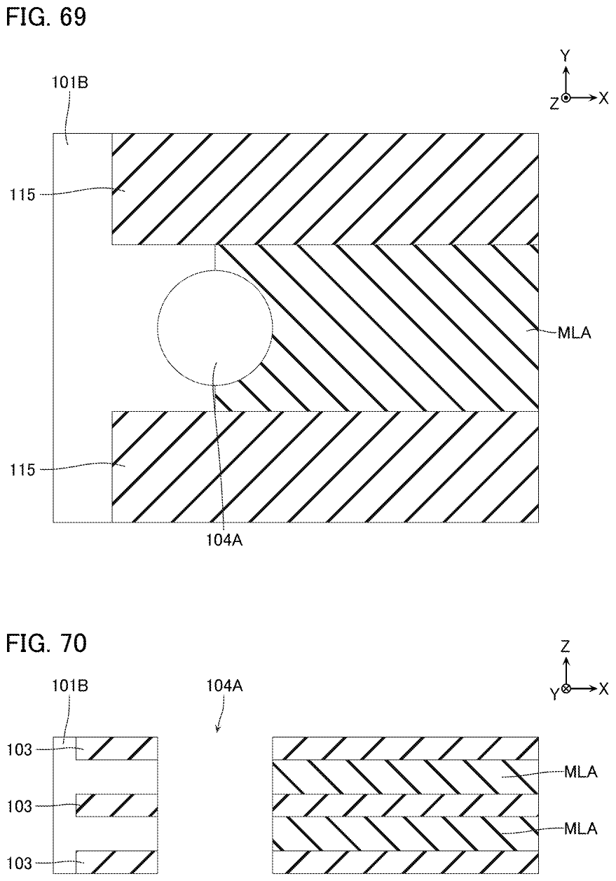

Next, as shown in FIGS. 69 and 70, for example, the sacrifice film 304A and the sacrifice layer 304B are removed. This step is performed by the likes of wet etching, for example.

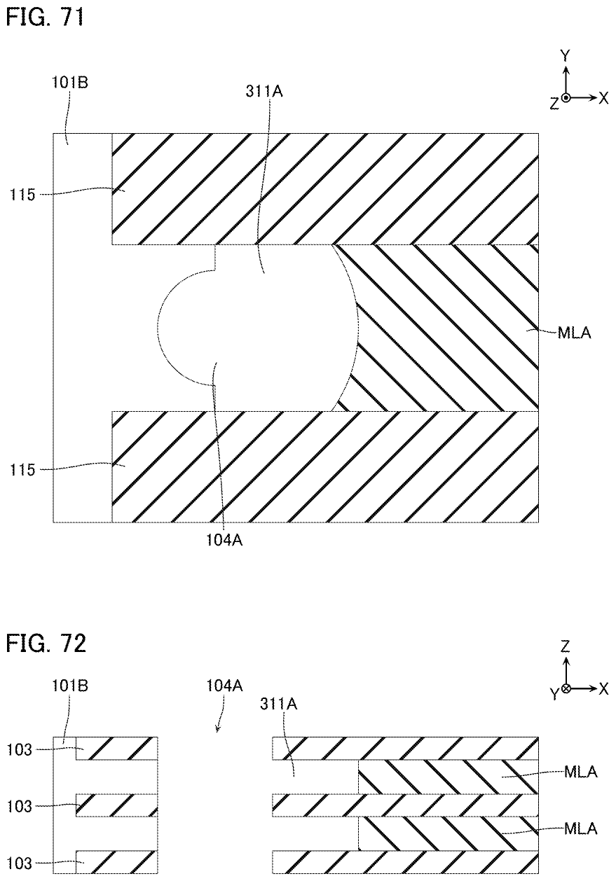

Next, as shown in FIGS. 71 and 72, for example, an opening 311A is formed at a position corresponding to the semiconductor layer 311. A part of the upper surface and a part of the lower surface of the insulating layer 103, a part of the side surface in the X-direction of the sacrifice layer MLA, a part of the side surface in the Y-direction of the insulating layer 115, and a part of the side surface in the X-direction of the sacrifice layer 101B are exposed inside the opening 311A. In this step, a part of the sacrifice layer MLA is selectively removed via the opening 104A, for example. This step is performed by the likes of wet etching, for example.

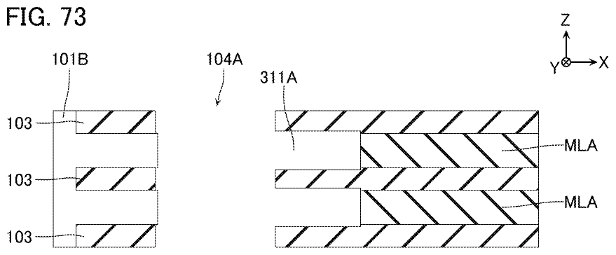

Next, as shown in FIG. 73, for example, a part of the insulating layer 103 is removed. This step is performed by the likes of wet etching, for example.

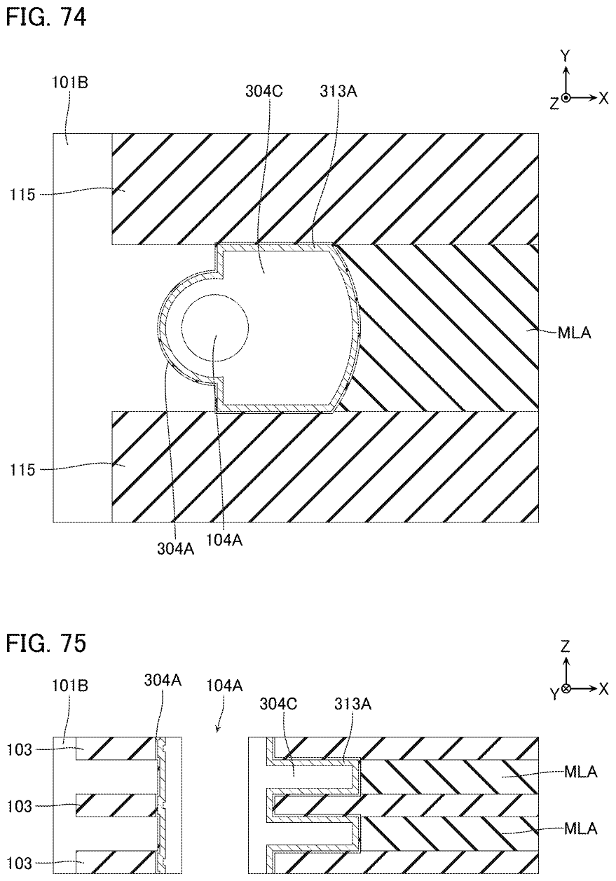

Next, as shown in FIGS. 74 and 75, for example, the sacrifice film 304A which is of the likes of silicon oxide (SiO₂), a conductive layer 313A, and a sacrifice layer 304C which is of the likes of silicon (Si), are formed inside the opening 311A and the opening 104A. The sacrifice layer 304A is formed on a part of the upper surface, a part of the lower surface, and the surface exposed to the opening 104A of the insulating layer 103, a part of the side surface in the X-direction of the sacrifice layer MLA, a part of the side surface in the Y-direction of the insulating layer 115, and a part of the side surface in the X-direction of the sacrifice layer 101B. Moreover, the opening 311A is embedded with the sacrifice layer 304C, but the opening 104A is not embedded with the sacrifice layer 304C. This step is performed by the likes of CVD, for example.

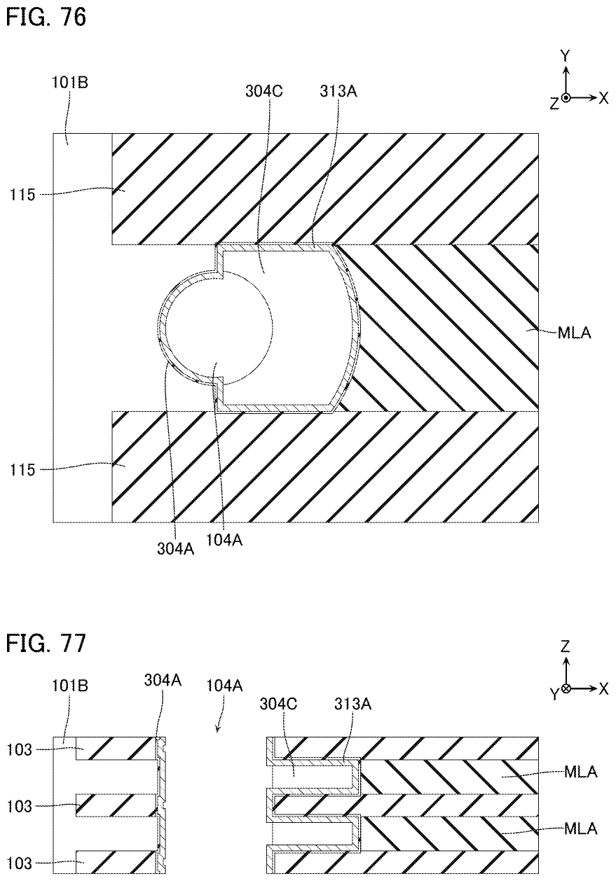

Next, as shown in FIGS. 76 and 77, for example, a part of the sacrifice layer 304C is removed to expose a portion provided on an inner peripheral surface of the opening 104A, of the conductive layer 313A, and divide the sacrifice layer 304C in the Z-direction. This step is performed by the likes of wet etching, for example.

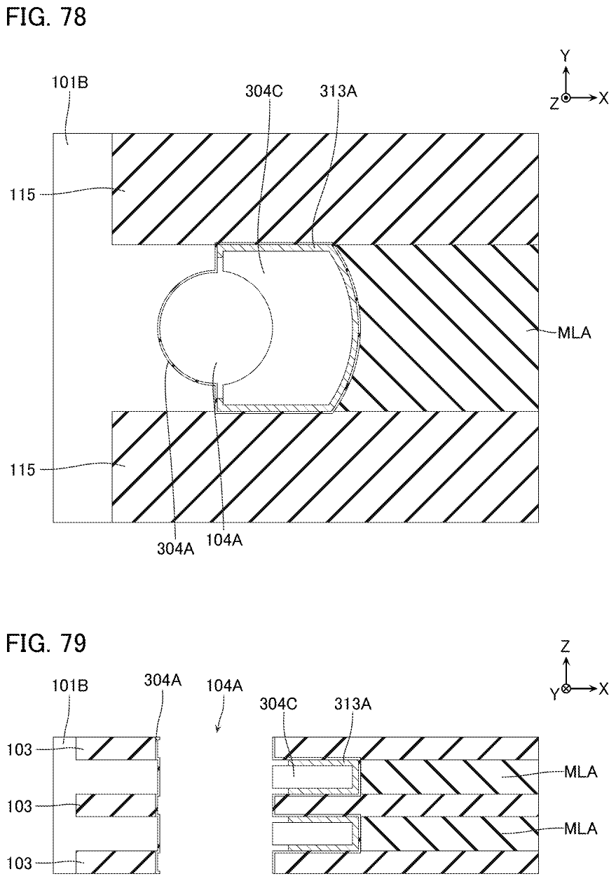

Next, as shown in FIGS. 78 and 79, for example, a part of the conductive layer 313A is removed to divide the conductive layer 313A in the Z-direction. In this step, a part of the sacrifice film 304A and parts of the plurality of insulating layers 103 arranged in the Z-direction are exposed inside the opening 104A. This step is performed by the likes of wet etching, for example.

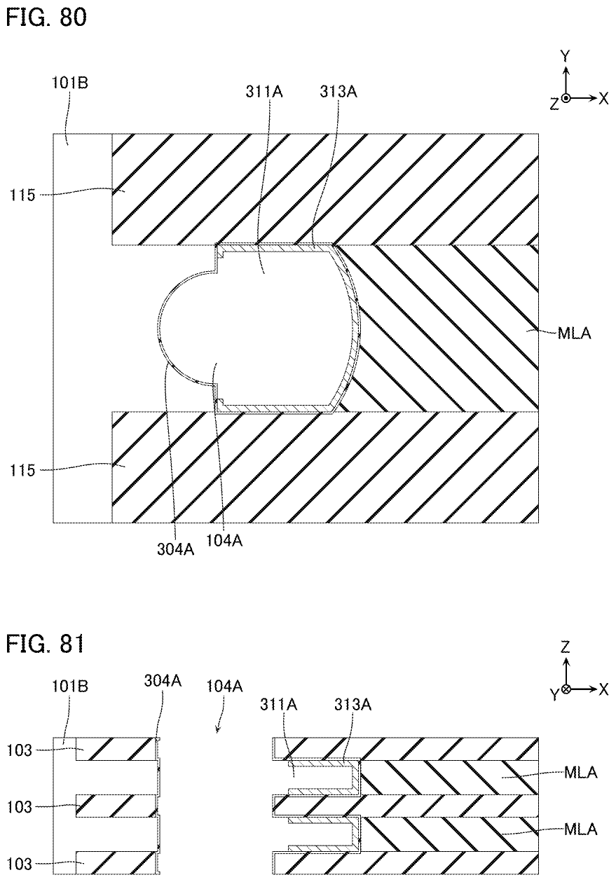

Next, as shown in FIGS. 80 and 81, for example, the sacrifice layer 304C is removed. This step is performed by the likes of wet etching, for example.

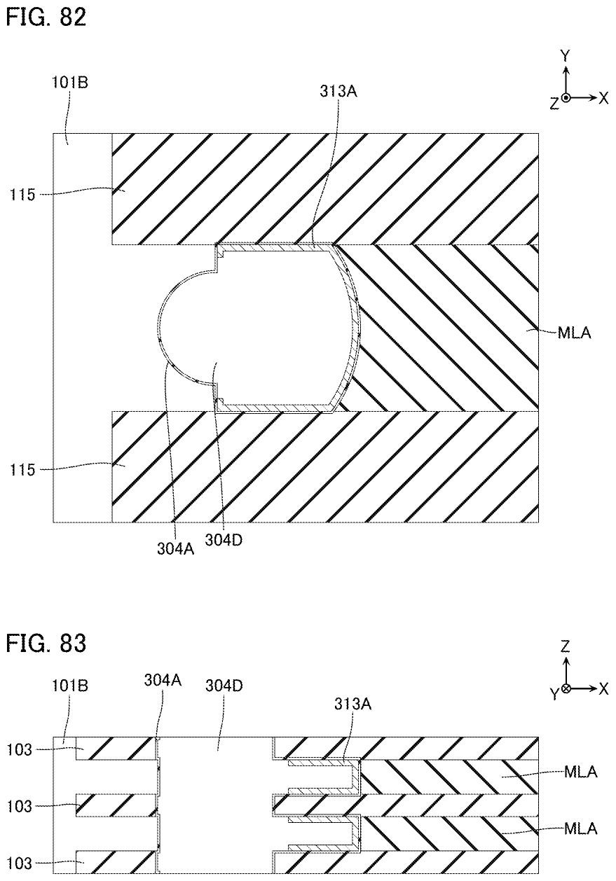

Next, as shown in FIGS. 82 and 83, for example, the opening 311A and the opening 104A are embedded with a sacrifice layer 304D of the likes of silicon (Si). This step is performed by the likes of CVD, for example.

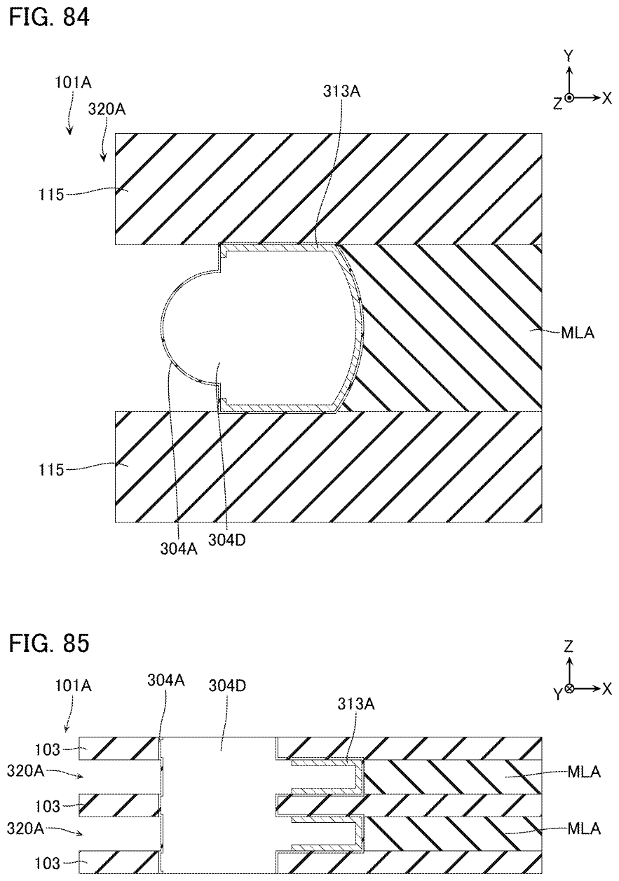

Next, as shown in FIGS. 84 and 85, for example, the sacrifice layer 101B is removed. This step is performed by the likes of wet etching, for example.

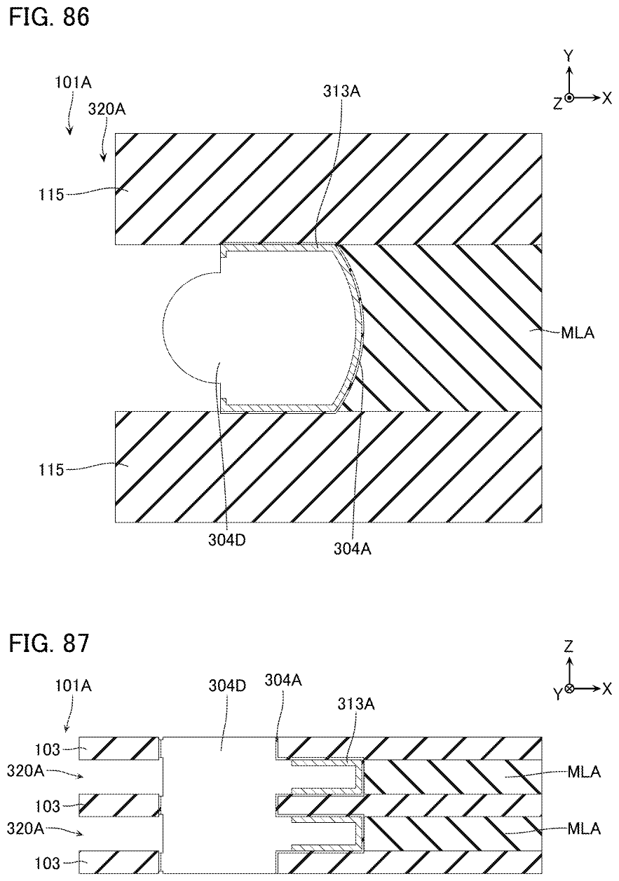

Next, as shown in FIGS. 86 and 87, for example, portions formed on end portions on one side (an opening 320A side) in the X-direction of the conductive layer 313A and a side surface on one side (the opening 320A side) in the X-direction of the sacrifice layer 304D, of the sacrifice film 304A are removed. This step is performed by the likes of wet etching, for example.

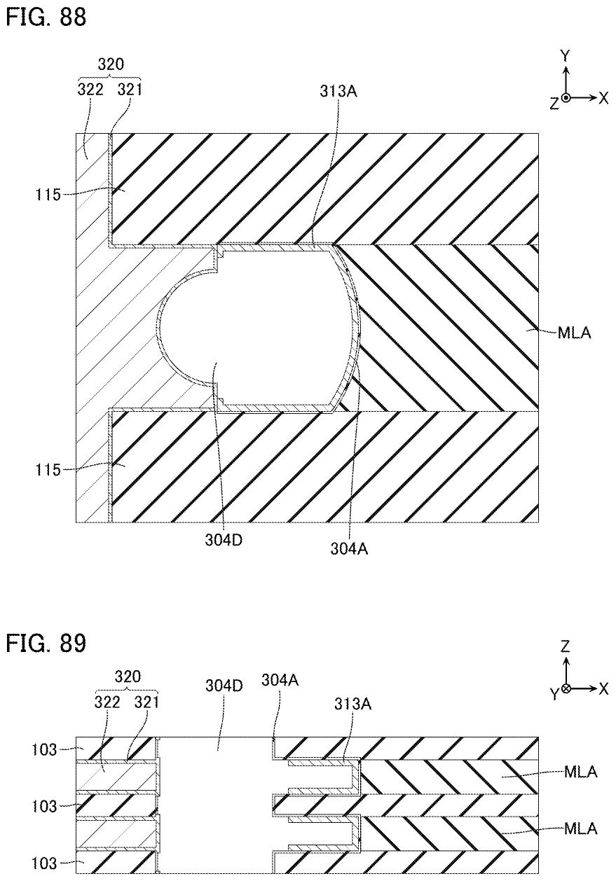

Next, as shown in FIGS. 88 and 89, for example, the conductive layer 320 is formed inside the opening 320A. This step is performed by the likes of CVD, for example.

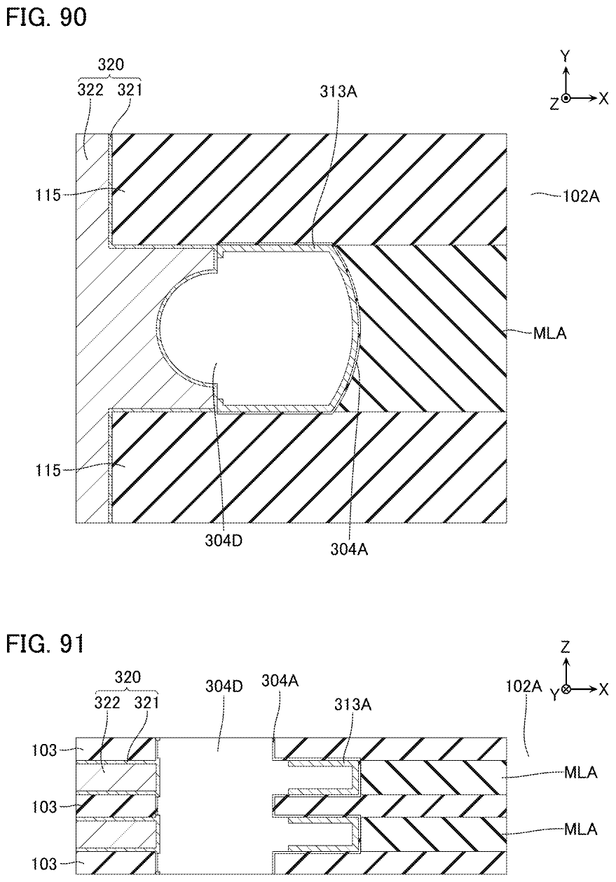

Next, as shown in FIGS. 90 and 91, for example, the opening 102A is formed at a position corresponding to the conductive layer 302. This step is performed by the likes of RIE, for example.

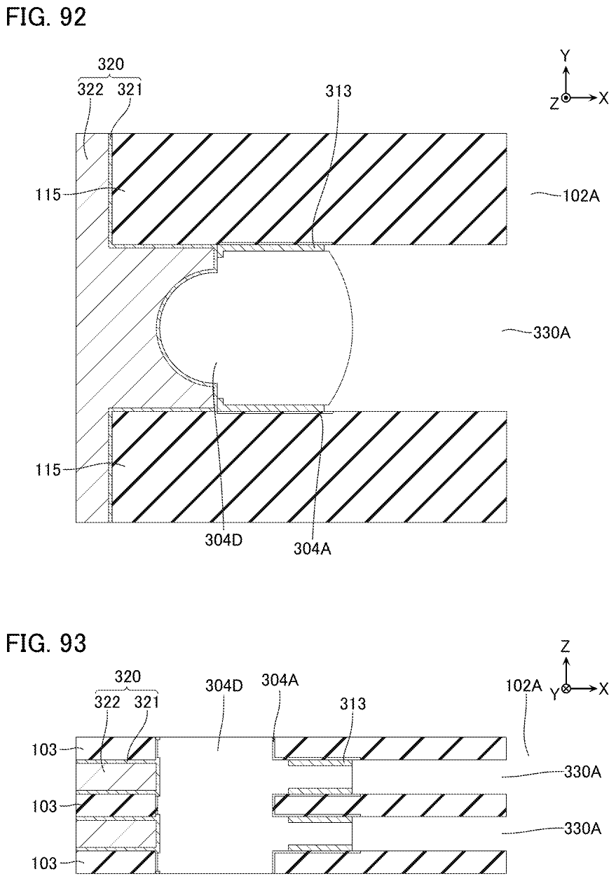

Next, as shown in FIGS. 92 and 93, for example, an opening 330A is formed at a position corresponding to the capacitor structure 330. In this step, the sacrifice layer MLA is removed via the opening 102A. Moreover, portions covering a side surface on one side (the side surface on the opening 102A side) in the X-direction of the sacrifice layer 304D, of the sacrifice film 304A and conductive layer 313A, are removed to form the conductive layer 313. In this step, the side surface in the X-direction of the sacrifice layer 304D is exposed inside the opening 102A. This step is performed by the likes of wet etching, for example.

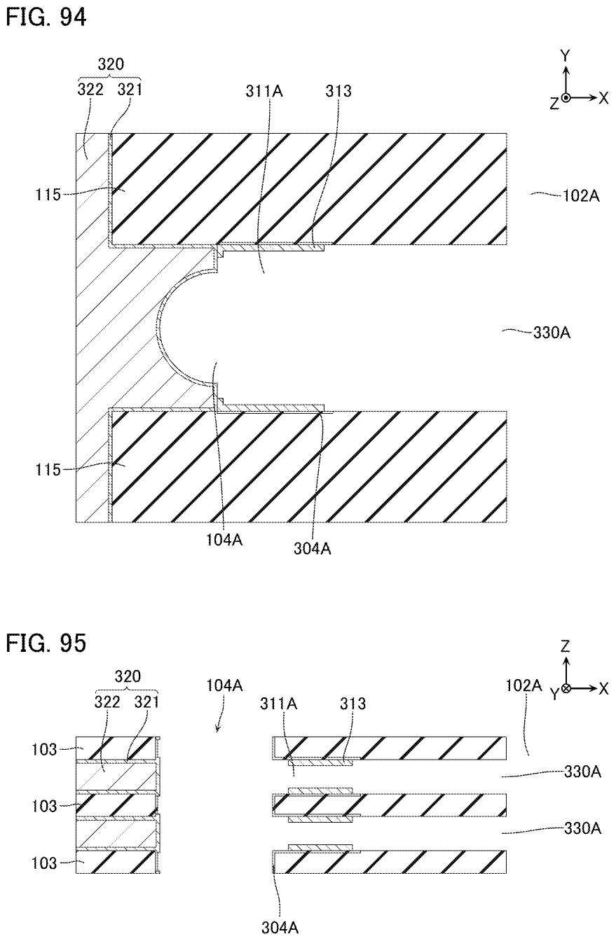

Next, as shown in FIGS. 94 and 95, for example, the sacrifice layer 304D is removed. This step is performed by the likes of wet etching, for example.

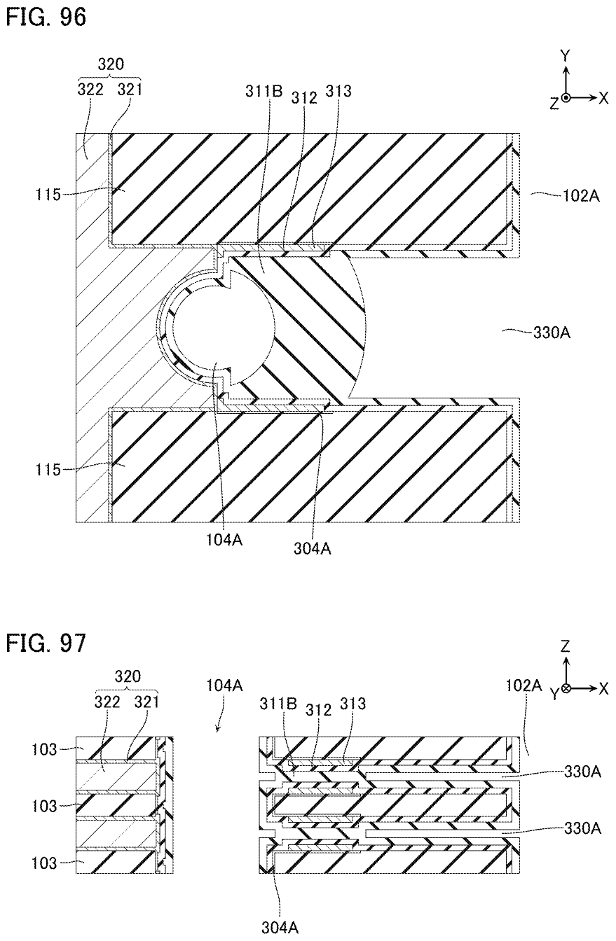

Next, as shown in FIGS. 96 and 97, for example, the insulating layer 312 and a sacrifice film 311B which is of the likes of silicon nitride (Si₃N₄) are formed inside the opening 104A, the opening 311A, the opening 330A, and the opening 102A. The opening 311A is embedded with the sacrifice film 311B, but the opening 104A, the opening 330A, and the opening 102A are not embedded with the sacrifice film 311B. This step is performed by the likes of CVD, for example. Note that after formation of the insulating layer 312 and the sacrifice film 311B, an upper portion of the opening 104A is blocked by an insulating layer, or the like, although illustration of this is omitted in the drawings.

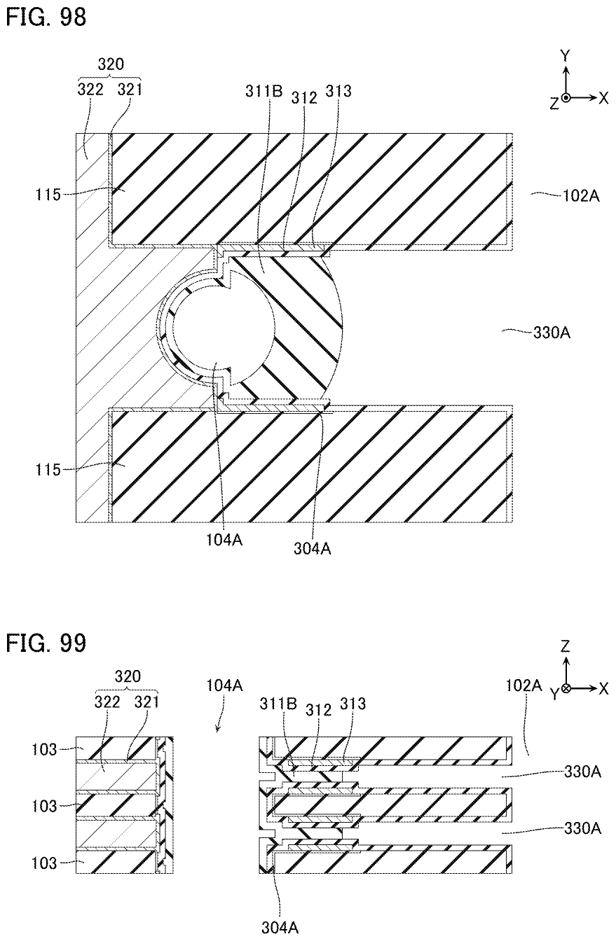

Next, as shown in FIGS. 98 and 99, for example, portions provided in the opening 330A and the opening 102A, of the sacrifice film 311B are removed. Moreover, in the example illustrated, a portion provided in the opening 311A, of the sacrifice film 311B is also partially removed. This step is performed by the likes of wet etching, for example.

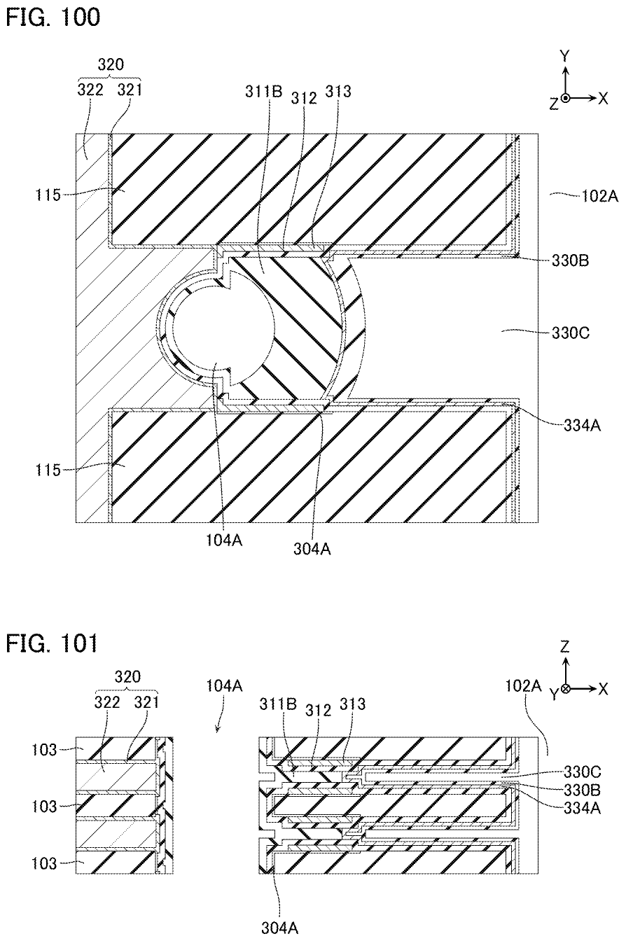

Next, as shown in FIGS. 100 and 101, for example, a conductive layer 334A, a sacrifice film 330B which is of the likes of silicon oxide (SiO₂), and a sacrifice layer 330C which is of the likes of silicon (Si) are formed inside the opening 102A, the opening 330A, and the opening 311A. In the example illustrated, a part of the opening 311A is embedded with the sacrifice film 330B. Moreover, the opening 330A is embedded with the sacrifice layer 330C, but the opening 102A is not embedded with the sacrifice layer 330C. This step is performed by the likes of CVD, for example.

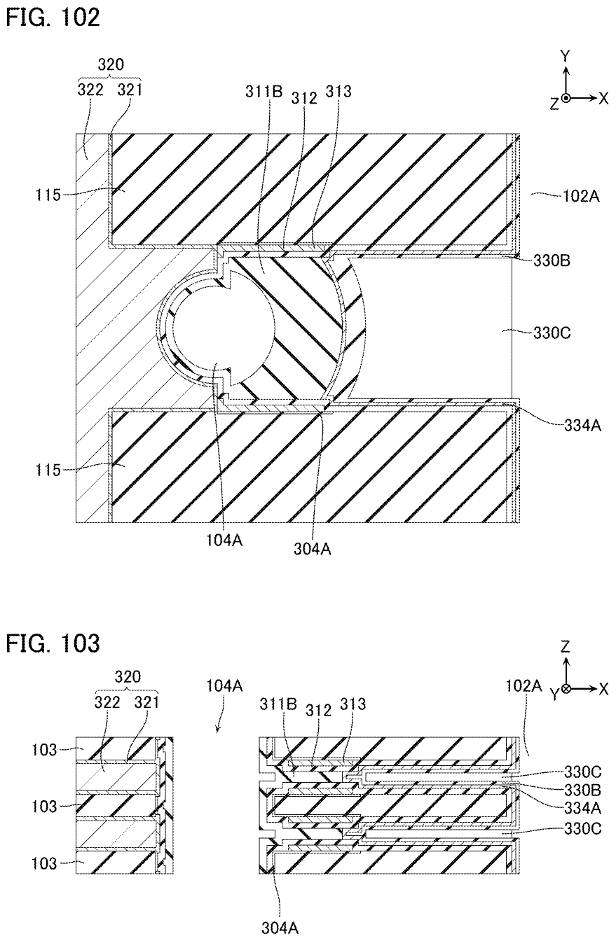

Next, as shown in FIGS. 102 and 103, for example, a portion provided on an inner wall surface of the opening 102A of the sacrifice layer 330C is removed and a portion provided on an inner wall surface of the opening 102A of the sacrifice film 330B exposed to divide the sacrifice layer 330C in the Z-direction and the Y-direction. This step is performed by the likes of wet etching, for example.

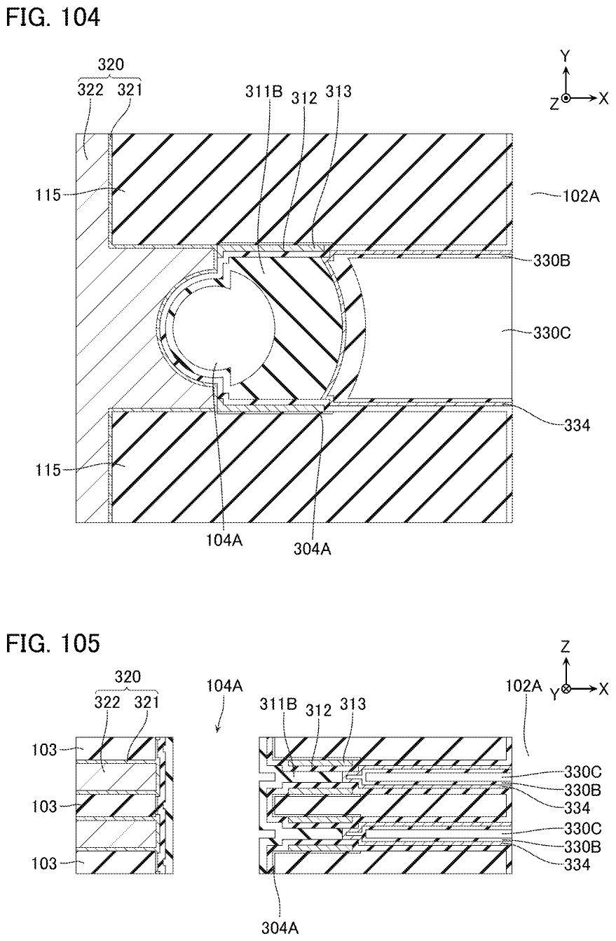

Next, as shown in FIGS. 104 and 105, for example, the conductive layer 334 is formed. In this step, for example, portions provided on the inner wall surface of the opening 102A, of the sacrifice film 330B and conductive layer 334A are removed to divide the conductive layer 334A in the Z-direction and the Y-direction. This step is performed by the likes of wet etching, for example.

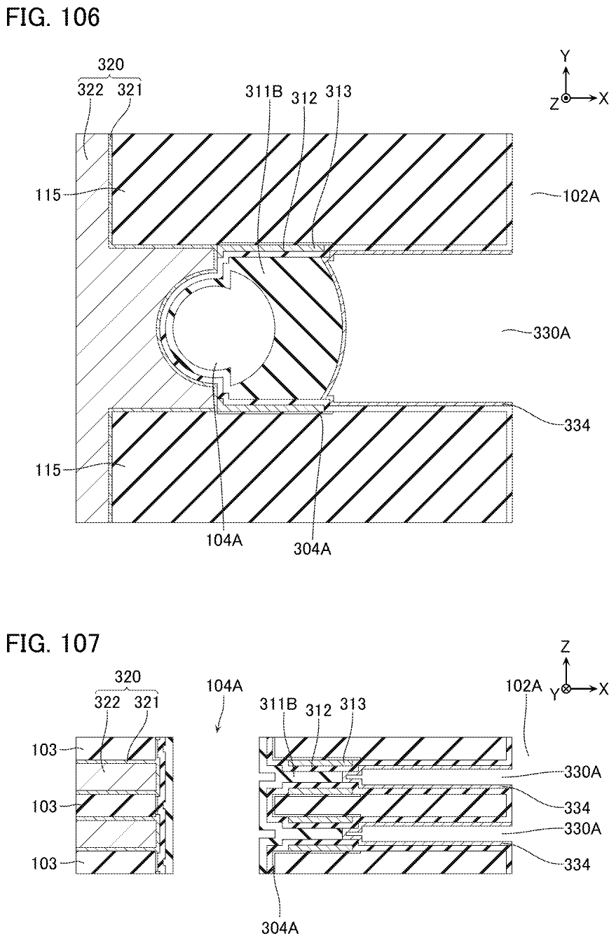

Next, as shown in FIGS. 106 and 107, for example, the sacrifice layer 330C and the sacrifice film 330B are removed. This step is performed by the likes of wet etching, for example.

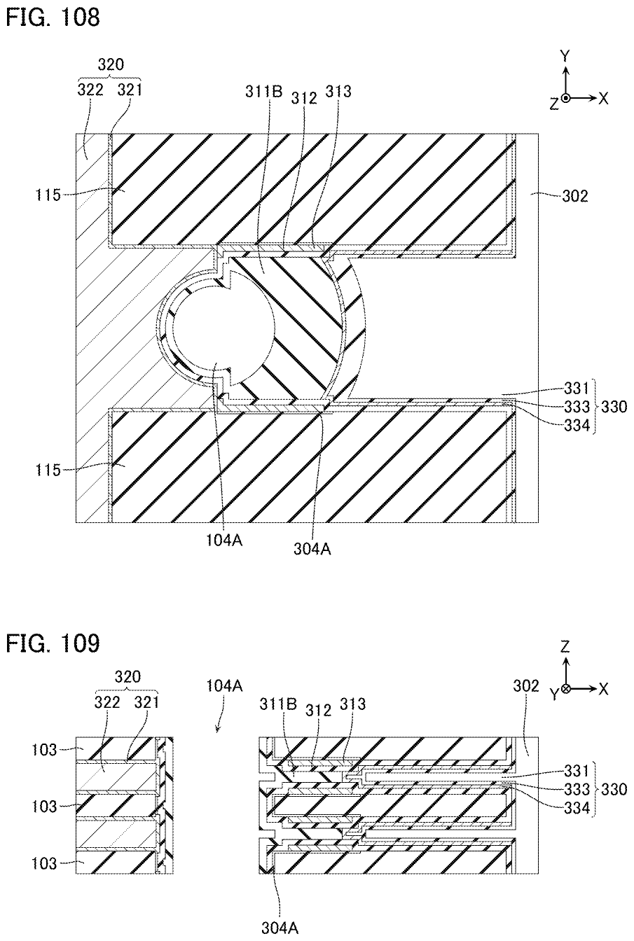

Next, as shown in FIGS. 108 and 109, for example, the capacitor structure 330 and the conductive layer 302 are formed inside the opening 330A and the opening 102A. This step is performed by the likes of ALD and CVD, for example.

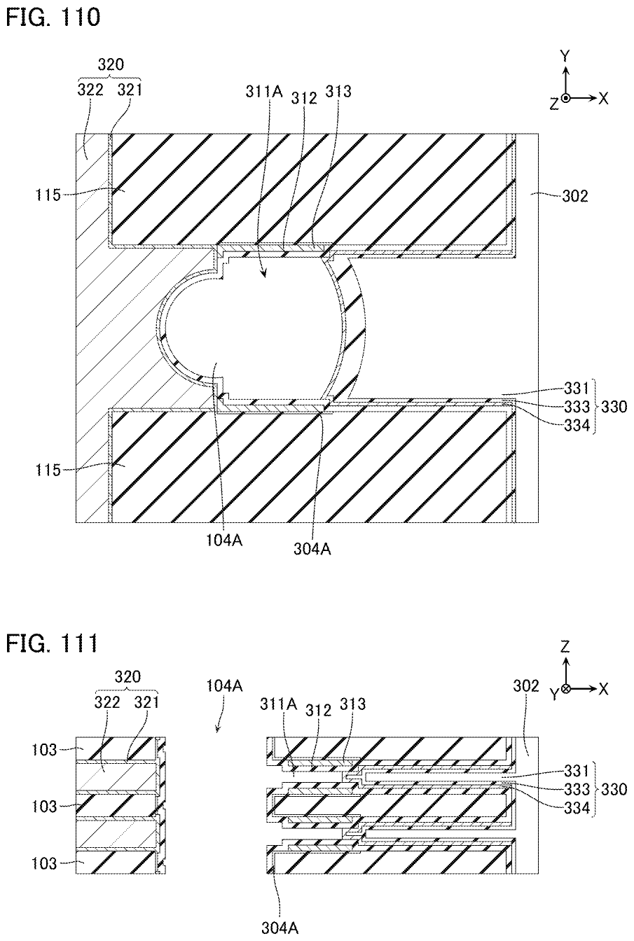

Next, as shown in FIGS. 110 and 111, for example, the sacrifice film 311B is removed. This step is performed by the likes of wet etching, for example.

Subsequently, as shown in FIGS. 61 and 62, for example, the via wiring 304 is formed inside the opening 104A. This step is performed by the likes of ALD and CVD, for example.

### Fourth Embodiment

### [Outline]

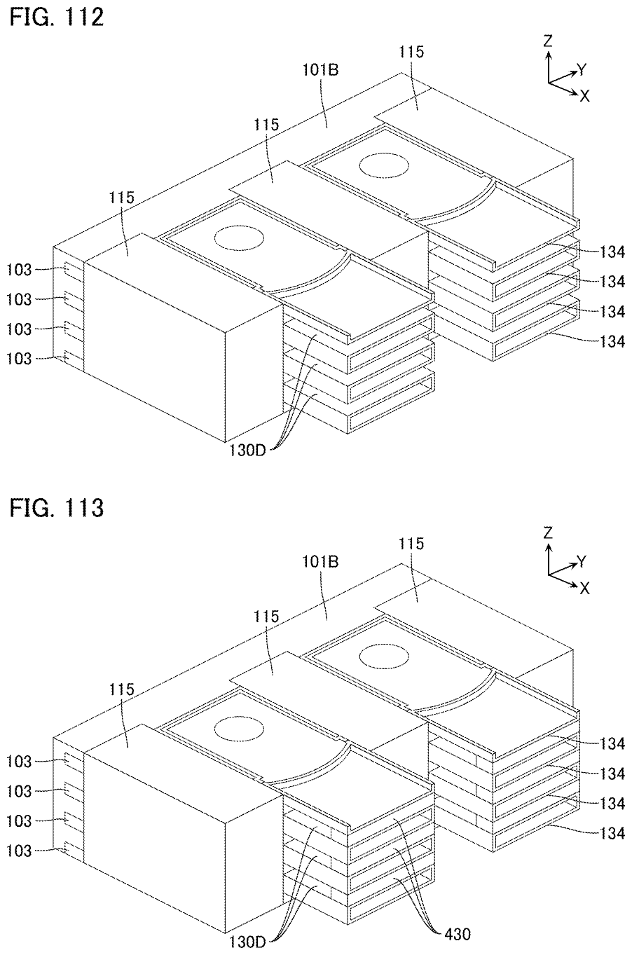

Next, an outline of a semiconductor memory device according to a fourth embodiment will be described with reference to FIGS. 112 and 113. In the following description, configurations similar to in the first embodiment will be assigned with the same symbols as in the first embodiment, and descriptions thereof omitted.

FIG. 112 is a schematic perspective view for explaining the method of manufacturing the semiconductor memory device according to the first embodiment. FIG. 113 is a schematic perspective view for explaining a method of manufacturing the semiconductor memory device according to the fourth embodiment.

During manufacturing of the semiconductor memory device according to the first embodiment, in the step described with reference to FIGS. 48 and 49, a part of the insulating layer 115 and a part of the insulating layer 103 are removed. At this time, a structure in which the conductive layer 134 projects in the X-direction, is formed, as shown in FIG. 112.

Now, depending on a length in the X-direction and a length in the Y-direction of the conductive layer 134, there is a risk that the conductive layer 134 warps due to effects of internal stress of the conductive layer 134 and stress in another structure in a vicinity of the conductive layer 134. As a result, there is a risk that characteristics of the capacitor CpC differ from a design value or that it becomes difficult for the semiconductor memory device to be formed.

Accordingly, in the fourth embodiment, as shown in FIG. 113, an insulating layer 430 is provided between a plurality of the conductive layers 134 arranged in the Z-direction, whereby the conductive layer 134 is supported.

### [Method of Manufacturing]

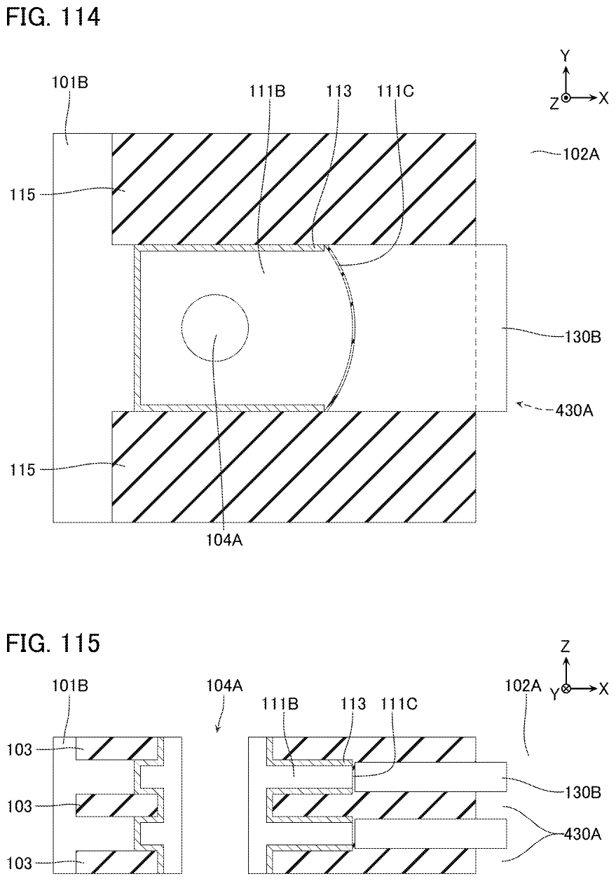

FIGS. 114 to 122 are schematic cross-sectional views for explaining the method of manufacturing the semiconductor memory device according to the fourth embodiment.

The semiconductor memory device according to the present embodiment is manufactured similarly to the semiconductor memory device according to the first embodiment, up to the step described with reference to FIGS. 24 and 25.

Next, as shown in FIGS. 114 and 115, for example, a part of the insulating layer 115 and a part of the insulating layer 103 are removed via the opening 102A. In this step, a part of the sacrifice layer 130B becomes a projection projecting into the opening 102A. An opening 430A corresponding to the insulating layer 430 is formed between a plurality of the projections arranged in the Z-direction. This step is performed by the likes of wet etching, for example.

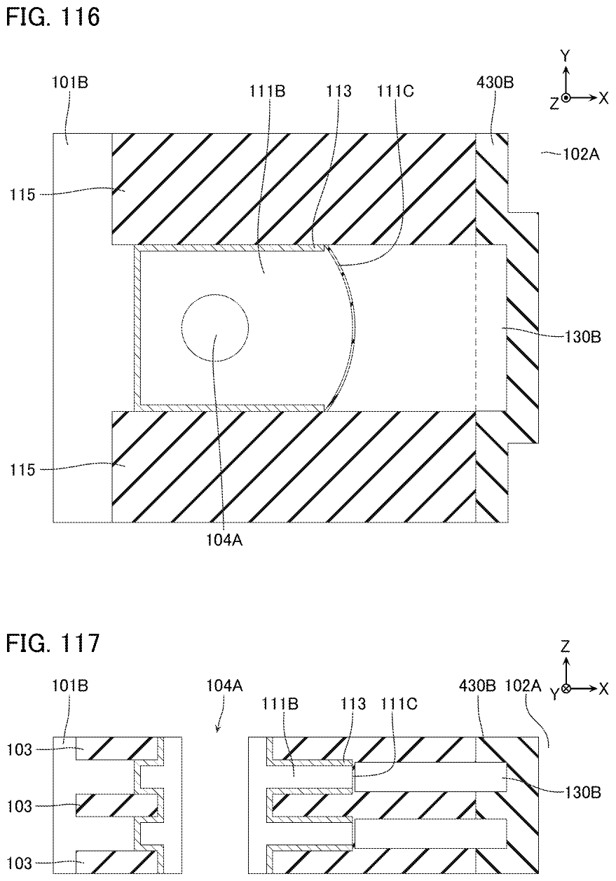

Next, as shown in FIGS. 116 and 117, for example, an insulating layer 430B of the likes of silicon nitride (Si₃N₄) is formed inside the opening 430A and the opening 102A. In this step, the insulating layer 430B is formed on a side surface on one side (a surface exposed to the opening 102A) in the X-direction of the insulating layer 115, and side surfaces on one side (surfaces exposed to the opening 102A) in the X-direction, upper surfaces, lower surfaces, and both side surfaces in the Y-direction of the above-described projections of a plurality of the sacrifice layers 130B arranged in the Z-direction. The opening 430A is embedded with the insulating layer 430B, but the opening 102A is not embedded with the insulating layer 430B. This step is performed by the likes of CVD, for example.

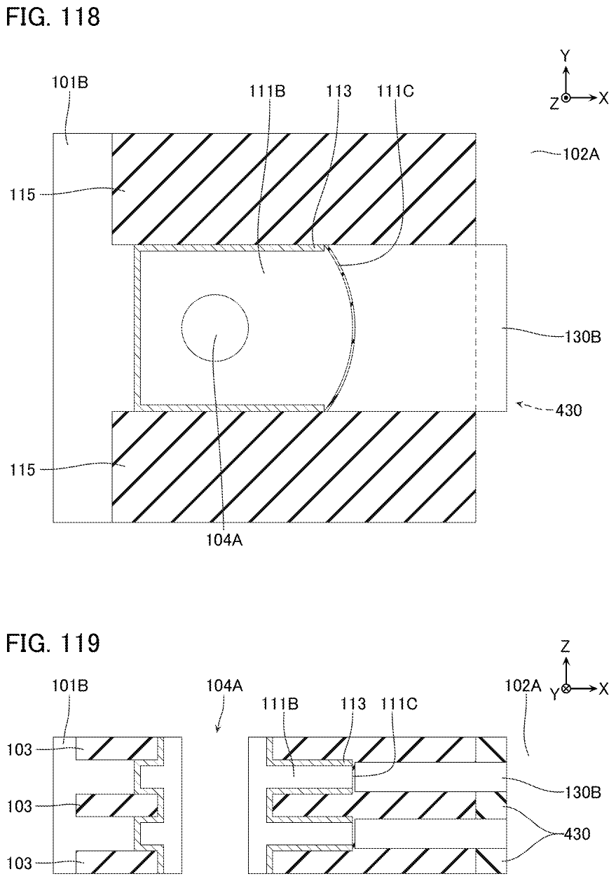

Next, as shown in FIGS. 118 and 119, for example, a part of the insulating layer 430B is removed to form the insulating layer 430. In this step, a portion formed on the side surface on one side (the surface exposed to the opening 102A) in the X-direction of the insulating layer 115, and portions formed on the side surfaces on one side (the surfaces exposed to the opening 102A) in the X-direction of the plurality of sacrifice layers 130B arranged in the Z-direction, of the insulating layer 430B are removed, and the insulating layer 430B is divided in the Y-direction and the Z-direction. This step is performed by the likes of wet etching, for example.

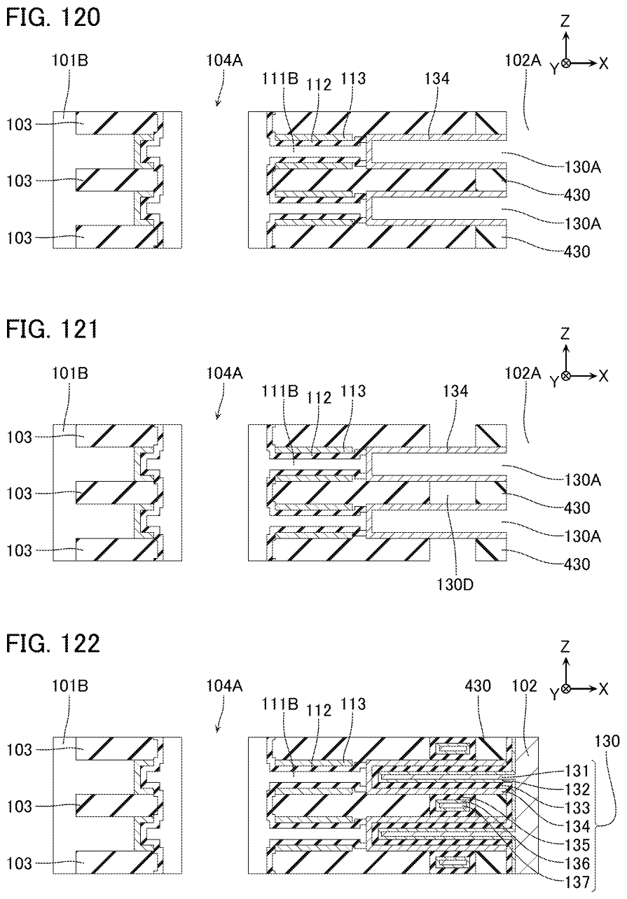

Next, the steps from the step described with reference to FIGS. 26 and 27 to the step described with reference to FIGS. 46 and 47 are executed. As a result, a structure of the kind shown in FIG. 120 is formed.

Next, as shown in FIGS. 121 and 113, for example, a part of the insulating layer 115 and a part of the insulating layer 103 are further removed via the opening 102A to form the opening 130D. Note that in this step, portions provided above and below the conductive layer 134, of the insulating layer 103 are exposed to the opening 102A on both side surfaces in the Y-direction (refer to FIG. 113). The insulating layer 103 is removed from such portions.

Next, as shown in FIG. 122, for example, the insulating layers 133, 135, the conductive layers 132, 136, and the conductive layers 131, 137, 102 are formed on the upper surface, the lower surface, the side surface on one side (the side surface on the opening 102A side) in the X-direction, and both side surfaces in the Y-direction of the conductive layer 134, and both side surfaces in the X-direction and the Y-direction of the insulating layer 430B, via the opening 130A, opening 130D, and the opening 102A. This step is performed by the likes of CVD, for example.

Subsequently, the steps from the step described with reference to FIGS. 52 and 53 onward, of the method of manufacturing the semiconductor memory device according to the first embodiment are executed, whereby the semiconductor memory device according to the fourth embodiment is formed.

### [Structure]

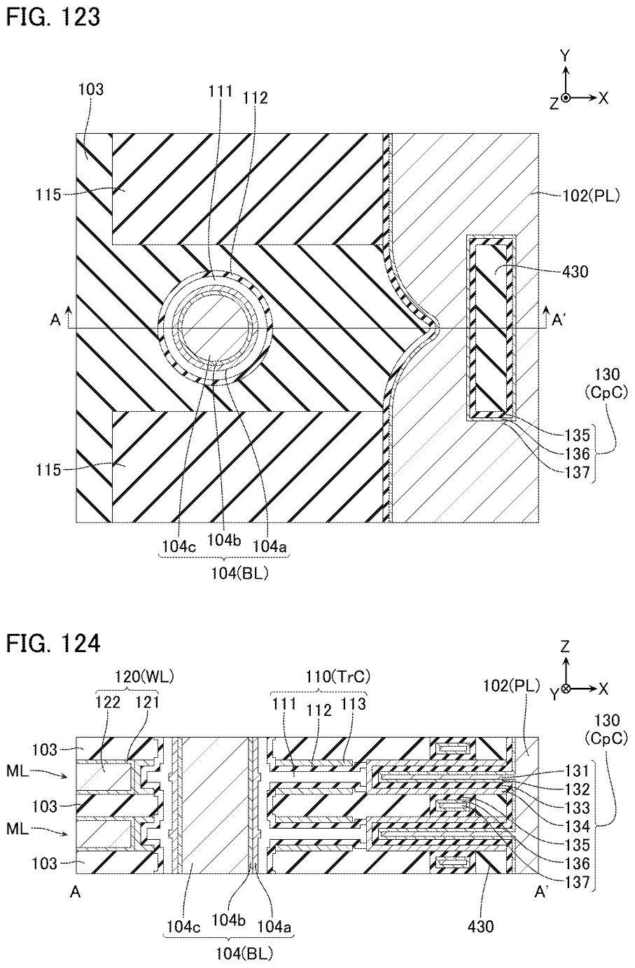

Next, configurations of the semiconductor memory device according to the fourth embodiment will be described with reference to FIGS. 123 and 124. FIG. 123 is a schematic XY cross-sectional view showing a part of a configuration of the semiconductor memory device. However, FIG. 123 shows an XY cross-sectional view at a height position corresponding to the insulating layer 103, not an XY cross-sectional view at a height position corresponding to the memory layer ML. FIG. 124 is a schematic cross-sectional view showing a part of a configuration of the semiconductor memory device, and shows configurations when the structure shown in FIG. 123 has been cut along the line A-A′ and viewed along a direction of the arrows. In the following description, configurations similar to in the first embodiment will be assigned with the same symbols as in the first embodiment, and descriptions thereof omitted.

The semiconductor memory device according to the fourth embodiment is basically configured similarly to the semiconductor memory device according to the first embodiment.

However, the semiconductor memory device according to the fourth embodiment comprises a plurality of the insulating layers 430 arranged in the Z-direction. The insulating layer 430 includes the likes of silicon nitride (Si₃N₄), for example. The insulating layer 430 is provided at a position overlapping a part of the conductive layer 134 viewed from the Z-direction. An upper surface and a lower surface of the insulating layer 430 each contact the conductive layer 134. Moreover, the insulating layer 135, the conductive layer 136, and the conductive layer 137 are stacked on both side surfaces in the X-direction and both side surfaces in the Y-direction of the insulating layer 430.

Note that as mentioned above, in the step described with reference to FIGS. 121 and 113, as removal of the insulating layer 103 proceeds, an end portion (a corner in the XY cross section) on the opening 104A side in the X-direction of the insulating layer 430 will be exposed. Moreover, as removal of the insulating layer 103 further proceeds, portions of the insulating layer 103 (portions provided above and below the conductive layer 134) will be removed with central focuses on these corner portions in the XY cross section. For such a reason, as shown in FIG. 123, at a position where the insulating layer 103 overlaps the capacitor structure 130 viewed from the Z-direction, the insulating layer 103 will be formed with a shape of the kind where its central portion in the Y-direction projects in the X-direction. That is, the closer to the central portion in the Y-direction a position of an end portion on the conductive layer 102 side in the X-direction, at the position overlapping the capacitor structure 130 viewed from the Z-direction, of the insulating layer 103 is, the shorter a distance to the insulating layer 430 in the X-direction of that end portion will be.

### Fifth Embodiment

### [Outline]

For example, in the semiconductor memory device according to the first embodiment, in the case where the number of memory layers ML included in the memory cell array MCA has increased, and a length in the Z-direction of the via wiring 104 functioning as the bit line BL has increased, parasitic capacitance between the via wiring 104 and the semiconductor layer 111 in each memory layer ML increases. When the parasitic capacitance increases, then during a read operation, it becomes difficult for a voltage of the bit line BL to be increased or decreased due to charge of the capacitor CpC, and, as a result, it becomes difficult for data stored in a selected memory cell MC to be read by the sense amplifier circuit.

Accordingly, a semiconductor memory device according to a fifth embodiment comprises a configuration in which the bit line BL is divided into a plurality of sub-bit lines sBL, and it is possible for these plurality of sub-bit lines sBL to be selectively made electrically continuous with a main bit line mBL. This kind of configuration results in that during a read operation, it is possible for solely a selected sub-bit line sBL to be made electrically continuous with the main bit line mBL and for another sub-bit line sBL to be electrically isolated from the main bit line mBL, and for the read operation to thereby be suitably executed.

### [Configuration]

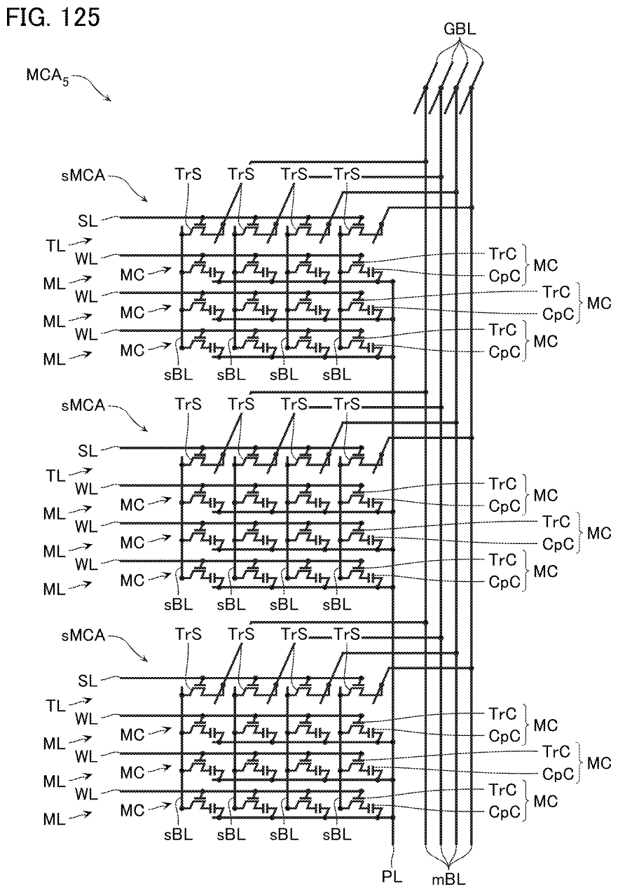

FIG. 125 is a schematic circuit diagram showing a part of a configuration of the semiconductor memory device according to the fifth embodiment. In the following description, configurations similar to in the first embodiment will be assigned with the same symbols as in the first embodiment, and descriptions thereof omitted.

The semiconductor memory device according to the present embodiment is basically configured similarly to the semiconductor memory device according to the first embodiment. However, the semiconductor memory device according to the present embodiment comprises a memory cell array MCA₅ instead of the memory cell array MCA.

The memory cell array MCA₅ comprises a plurality of sub-memory cell arrays sMCA. Each of the sub-memory cell arrays sMCA is basically configured similarly to the memory cell array MCA.

However, the sub-memory cell array sMCA comprises the sub-bit line sBL instead of the bit line BL. The sub-bit line sBL is basically configured similarly to the bit line BL. However, the sub-bit line sBL is connected to a plurality of the memory cells MC corresponding to the plurality of memory layers ML included in one sub-memory cell array sMCA, but is not connected to the memory cells MC included in another sub-memory cell array sMCA.

Moreover, the sub-memory cell array sMCA comprises a transistor layer TL in addition to the plurality of memory layers ML.

The transistor layers TL each comprise: a select line SL; and a plurality of transistors TrS connected to the select line SL. A source electrode of the transistor TrS is connected to the main bit line mBL. A drain electrode of the transistor TrS is connected to the sub-bit line sBL. A gate electrode of the transistor TrS is connected to the select line SL.

Note that the main bit line mBL is connected to all of the sub-memory cell arrays sMCA included in the memory cell array MCA₅. Moreover, a global bit line GBL is connected to a plurality of the main bit lines mBL, although illustration of this is omitted in the drawings.

### [Operation]

During the read operation, the select line SL corresponding to one of the plurality of sub-memory cell arrays sMCA (hereafter, referred to as “selected sub-memory cell array sMCA”) is applied with a voltage that will set the transistor TrS to an ON state, and the select line SL corresponding to another sub-memory cell array sMCA (hereafter, referred to as “unselected sub-memory cell array sMCA”) is applied with a voltage that will set the transistor TrS to an OFF state. As a result, the global bit line GBL and the sub-bit line sBL which is in the selected memory cell array sMCA, are electrically continuous. Moreover, the global bit line GBL and the sub-bit line sBL which is in the unselected memory cell array sMCA, are electrically isolated.

Moreover, in the selected sub-memory cell array sMCA, the word line WL corresponding to one of the plurality of memory layers ML (hereafter, referred to as “selected memory layer ML”) is applied with a voltage that will set the transistor TrC to an ON state, and the word line WL corresponding to another memory layer ML (hereafter, referred to as “unselected memory layer ML”) is applied with a voltage that will set the transistor TrC to an OFF state. As a result, the sub-bit line sBL and the capacitor CpC which is in the selected memory layer ML, are electrically continuous. Moreover, the sub-bit line sBL and the capacitor CpC which is in the unselected memory layer ML, are electrically isolated.

Due to the above operation, the global bit line GBL is electrically continuous with the capacitor CpC. Moreover, a voltage of the global bit line GBL increases or decreases according to charge in the capacitor CpC. The unillustrated sense amplifier circuit amplifies a differential of the voltage of the global bit line GBL and a reference voltage, and outputs the amplified differential to outside as read data.

### [Structure]

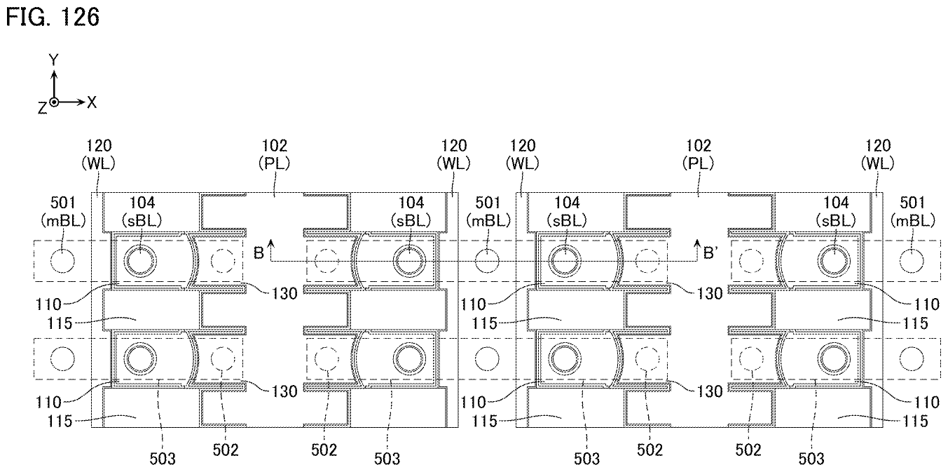

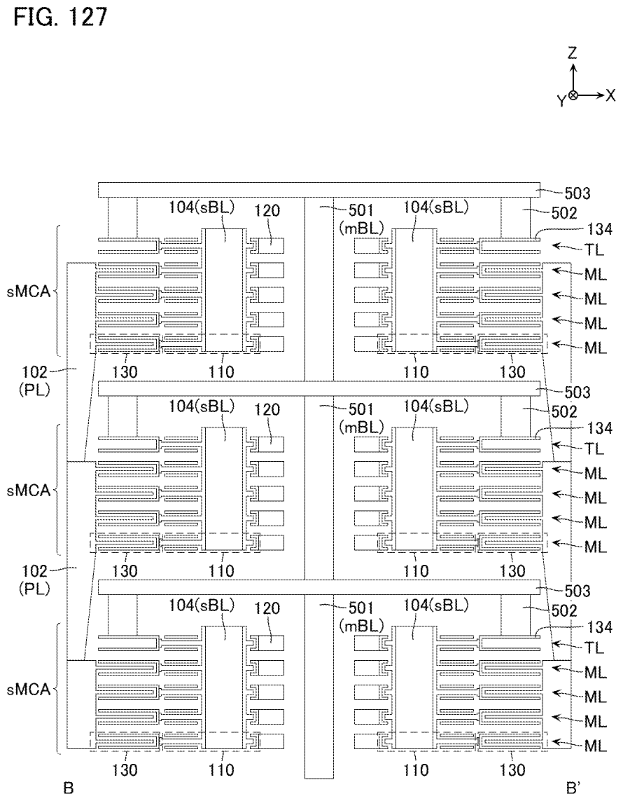

FIG. 126 is a schematic XY cross-sectional view showing a part of a configuration of the semiconductor memory device according to the fifth embodiment. Note that FIG. 126 basically shows an XY cross section at a height position corresponding to the memory layer ML. Moreover, in FIG. 126, configurations not present at this height position are illustrated by dotted lines. FIG. 127 is a schematic cross-sectional view showing a part of a configuration of the semiconductor memory device, and shows configurations when the structure shown in FIG. 126 has been cut along the line B-B′ and viewed along a direction of the arrows.

As shown in FIG. 127, in each of the sub-memory cell arrays sMCA, the transistor layer TL is disposed above all of the memory layers ML. The transistor layer TL is basically configured similarly to the memory layer ML. However, in the transistor layer TL, the transistor structure 110 functions as the transistor TrS. Moreover, the conductive layer 120 functions as the select line SL. Moreover, the conductive layer 134 functions as a part of a wiring electrically connected between the sub-bit line sBL and the main bit line mBL. Moreover, the transistor layer TL need not comprise a configuration in the capacitor structure 130 other than the conductive layer 134, as illustrated.

Moreover, the sub-memory cell array sMCA comprises: a via wiring 501 that functions as the main bit line mBL; and a via wiring 502 and a wiring 503 that electrically connect the main bit line mBL and the sub-bit line sBL (via wiring 104).

As shown in FIG. 126, the via wirings 501 are arranged in the X-direction and the Y-direction correspondingly to sets of two via wirings 104 adjacent in the X-direction, via the conductive layers 120. As shown in FIG. 127, the via wiring 501 extends in the Z-direction over the entire sub-memory cell array sMCA. Focusing on a single sub-memory cell array sMCA, a lower end of the via wiring 501 is located more downwardly than a lower surface of the lowermost layer-located memory layer ML. Moreover, an upper end of the via wiring 501 is located more upwardly than an upper surface of the transistor layer TL. The upper end of the via wiring 501 is connected to the wiring 503. The lower end of the via wiring 501 is connected to the wiring 503 included in the sub-memory cell array sMCA one below the sub-memory cell array sMCA including this via wiring 501.

As shown in FIG. 126, the via wirings 502 are arranged in the X-direction and the Y-direction correspondingly to a plurality of the via wirings 104. As shown in FIG. 127, the via wiring 502 extends in the Z-direction. A lower end of the via wiring 502 is connected to the conductive layer 134 in the transistor layer TL. An upper end of the via wiring 502 is connected to the wiring 503.

As shown in FIG. 126, the wirings 503 are arranged in the X-direction and the Y-direction correspondingly to a plurality of the via wirings 501. The wiring 503 extends in the X-direction, and is connected to the two via wirings 502 adjacent to it in the X-direction and to the via wiring 501 provided between these two via wirings 502.

### Sixth Embodiment

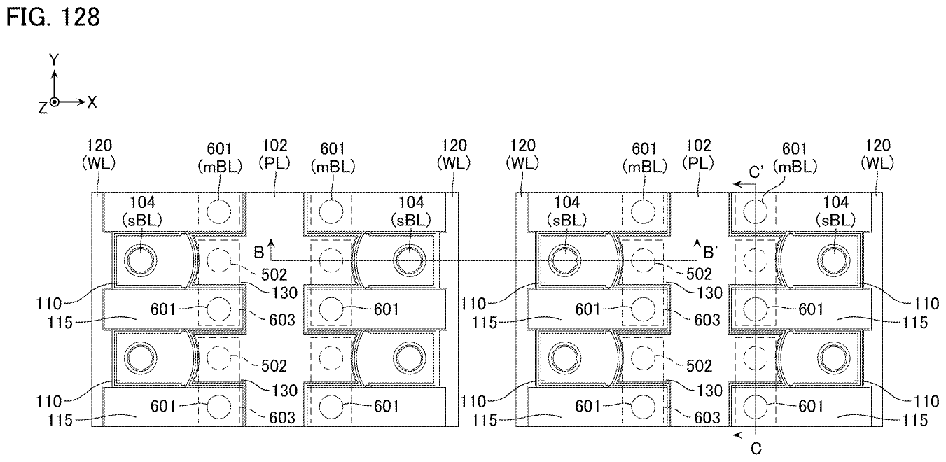

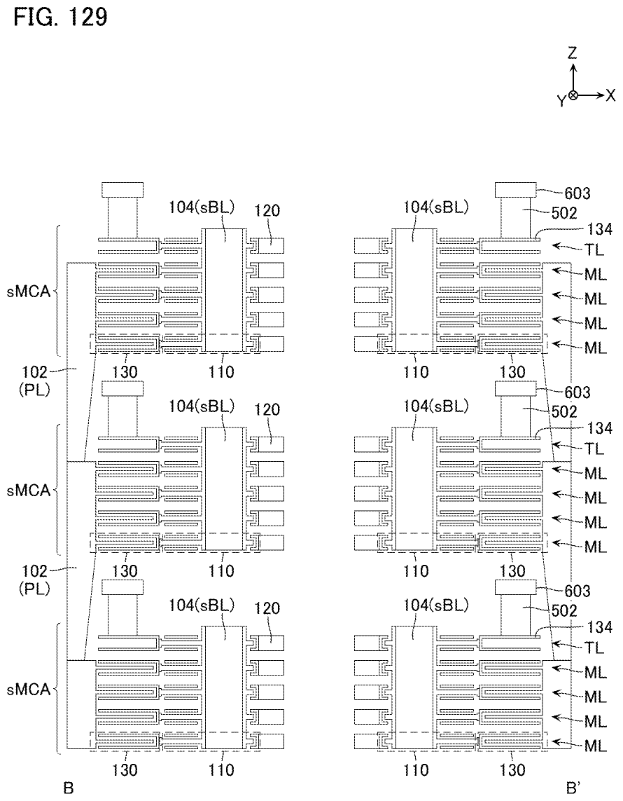

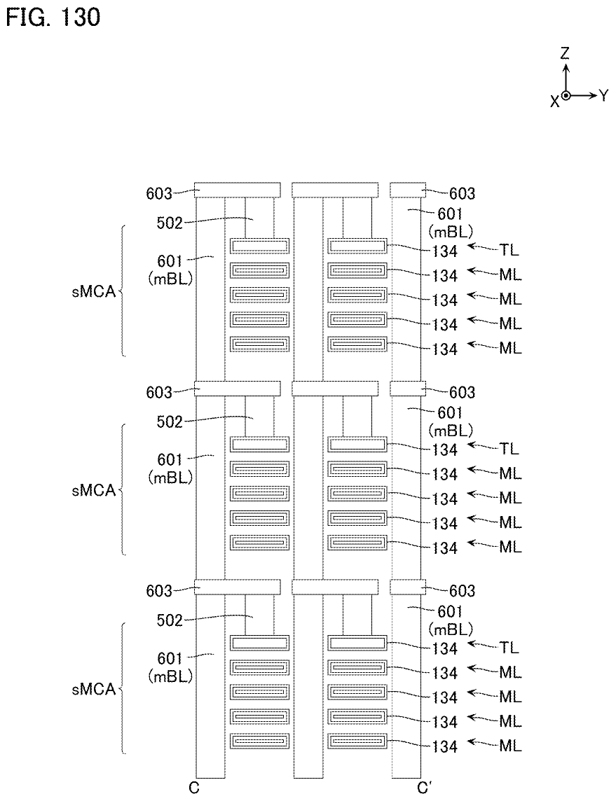

Next, a semiconductor memory device according to a sixth embodiment will be described with reference to FIGS. 128 to 130. FIG. 128 is a schematic XY cross-sectional view showing a part of a configuration of the semiconductor memory device. Note that FIG. 128 basically shows an XY cross section at a height position corresponding to the memory layer ML. Moreover, in FIG. 128, configurations not present at this height position are illustrated by dotted lines. FIG. 129 is a schematic cross-sectional view showing a part of a configuration of the semiconductor memory device, and shows configurations when the structure shown in FIG. 128 has been cut along the line B-B′ and viewed along a direction of the arrows. FIG. 130 is a schematic cross-sectional view showing a part of a configuration of the semiconductor memory device, and shows configurations when the structure shown in FIG. 128 has been cut along the line C-C′ and viewed along a direction of the arrows. In the following description, configurations similar to in the fifth embodiment will be assigned with the same symbols as in the fifth embodiment, and descriptions thereof omitted.

The semiconductor memory device according to the sixth embodiment is basically configured similarly to the semiconductor memory device according to the fifth embodiment. However, the semiconductor memory device according to the sixth embodiment comprises a via wiring 601 and a wiring 603, instead of the via wiring 501 and the wiring 503.

The via wiring 601 is basically configured similarly to the via wiring 501. However, as shown in FIG. 128, the via wirings 601 are arranged in the X-direction and the Y-direction correspondingly to a plurality of the via wirings 502. The via wirings 601 are each provided between two via wirings 502 adjacent in the Y-direction. Moreover, as shown in FIG. 130, an upper end of the via wiring 601 is connected to the wiring 603. Moreover, a lower end of the via wiring 601 is connected to the wiring 603 included in the sub-memory cell array sMCA one below the sub-memory cell array sMCA including this via wiring 601.

The wiring 603 is basically configured similarly to the wiring 503. However, as shown in FIG. 128, the wirings 503 are arranged in the X-direction and the Y-direction correspondingly to a plurality of the via wirings 502. The wiring 603 extends in the Y-direction, and is connected to one via wiring 601 and one via wiring 502.

### Seventh Embodiment

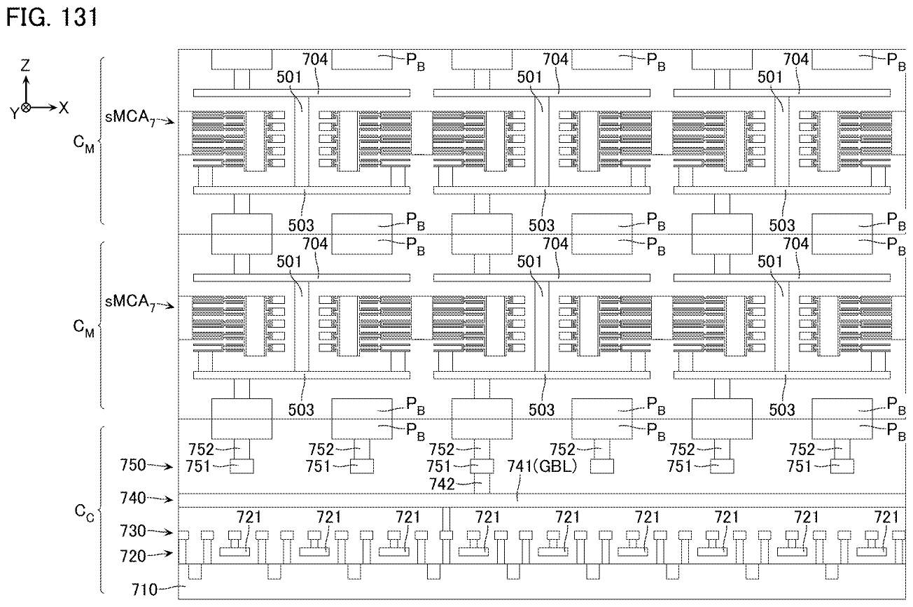

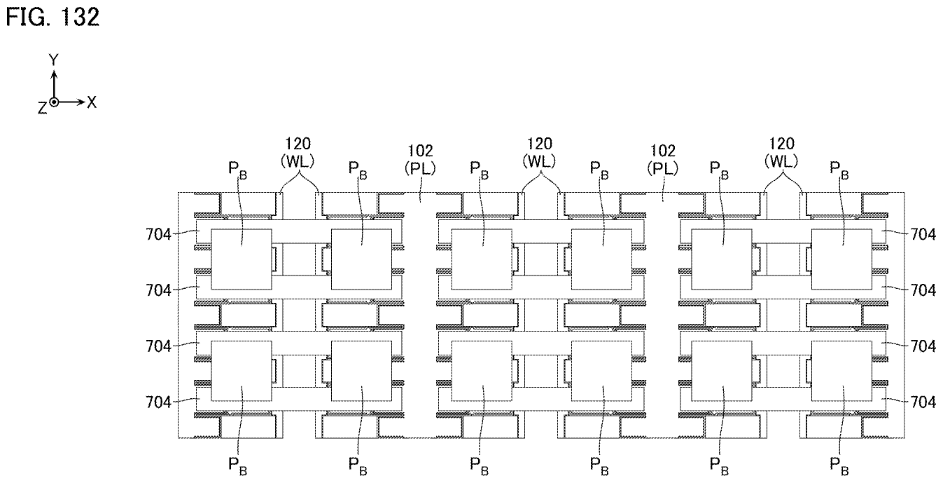

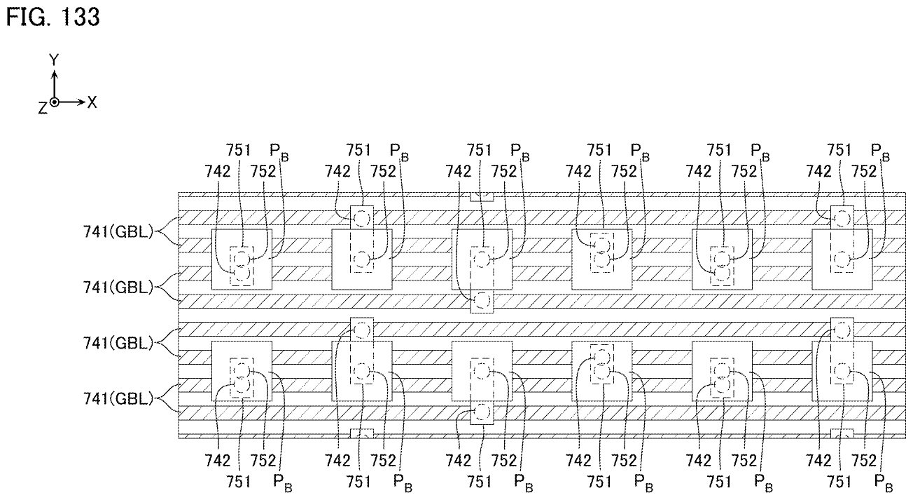

Next, a semiconductor memory device according to a seventh embodiment will be described with reference to FIGS. 131 to 133. FIG. 131 is a schematic cross-sectional view showing a part of a configuration of the semiconductor memory device. FIG. 132 is a schematic XY cross-sectional view showing configurations of a memory chip C_{M}. Note that FIG. 132 basically shows an XY cross section at a height position corresponding to the memory layer ML. However, in FIG. 132, configurations not present at this height position (a bonding electrode P_{B} and a wiring 704) are illustrated. FIG. 133 is a schematic plan view showing configurations of a peripheral circuit chip C_{C}. In the following description, configurations similar to in the fifth embodiment will be assigned with the same symbols as in the fifth embodiment, and descriptions thereof omitted.

As shown in FIG. 131, the semiconductor memory device according to the seventh embodiment comprises: a plurality of the memory chips C_{M} stacked in the Z-direction; and the peripheral circuit chip C_{C} provided below these plurality of memory chips C_{M}.

The memory chip C_{M} comprises a sub-memory cell array sMCA₇. The sub-memory cell array sMCA₇ is basically configured similarly to the sub-memory cell array sMCA described with reference to FIGS. 125 to 127. However, the sub-memory cell array sMCA₇ and the sub-memory cell array sMCA are configured reversely in an up-down direction. Moreover, the sub-memory cell array sMCA₇ comprises the wiring 704 which is connected to the upper end of the via wiring 501. The wiring 704 is basically configured similarly to the wiring 503. However, the wiring 704 is provided above rather than below the memory layer ML, hence is not connected to the lower end of the via wiring 502.

Moreover, an upper surface and a lower surface of the memory chip C_{M} are provided with a plurality of the bonding electrodes P_{B}. The bonding electrodes P_{B} at the upper surface of the memory chip C_{M} are each provided correspondingly to any of the wirings 704. The bonding electrodes P_{B} at the lower surface of the memory chip C_{M} are each provided correspondingly to any of the wirings 503. In the example of FIG. 132, the bonding electrodes P_{B} are arranged in the X-direction with a pitch half that of the wirings 704 (at their lower surface, with a pitch half that of the wirings 503). Moreover, the bonding electrodes P_{B} are arranged in the Y-direction with a pitch twice that of the wirings 704 (at their lower surface, with a pitch twice that of the wirings 503). The bonding electrodes P_{B} are respectively electrically connected to the via wirings 501 (FIG. 131) via the wiring 503 or the wiring 704. Moreover, the bonding electrode P_{B} is connected to the bonding electrode P_{B} in another memory chip C_{M} or to the bonding electrode P_{B} in the peripheral circuit chip C_{C}.

As shown in FIG. 131, the peripheral circuit chip C_{C} comprises: a semiconductor substrate 710; an electrode layer 720 provided above the semiconductor substrate 710; a wiring layer 730 provided above the electrode layer 720; a wiring layer 740 provided above the wiring layer 730; and a wiring layer 750 provided above the wiring layer 740.

The semiconductor substrate 710 is configured similarly to the semiconductor substrate Sub described with reference to FIG. 2, for example.

The electrode layer 720 includes a plurality of electrodes 721. The plurality of electrodes 721 respectively face active regions of a surface of the semiconductor substrate 710, and together with the plurality of active regions, configure a plurality of transistors. The plurality of transistors, which are N channel type or P channel type field effect transistors, configure a part of the sense amplifier circuit.

The wiring layer 730 includes a plurality of wirings. The plurality of wirings are respectively connected to a source electrode, a drain electrode, or a gate electrode of the above-described transistor, via a via contact electrode.

The wiring layer 740 includes a plurality of wirings 741. The plurality of wirings 741 respectively function as the global bit lines GBL. As shown in FIG. 133, the plurality of wirings 741 are arranged in the Y-direction, and extend in the X-direction. As shown in FIG. 131, the plurality of wirings 741 are connected to the source electrode or the drain electrode of the above-described transistor, via the via contact electrode.

The wiring layer 750 includes a plurality of wirings 751. The plurality of wirings 751 are respectively connected to the wirings 741, via a via contact electrode 742.

Moreover, an upper surface of the peripheral circuit chip C_{C} is provided with a plurality of the bonding electrodes P_{B}. These plurality of bonding electrodes P_{B} are respectively connected to the wirings 751, via a via contact electrode 752. Moreover, the bonding electrode P_{B} is connected to the bonding electrode P_{B} in the memory chip C_{M}.

In the example of FIG. 133, the bonding electrodes P_{B} are arranged in the X-direction and the Y-direction. The bonding electrodes P_{B} are each provided correspondingly to any of the wirings 741. The bonding electrodes P_{B} are arranged in the Y-direction with a pitch four times that of the wirings 741. The via contact electrodes 752 are arranged in the X-direction and the Y-direction correspondingly to the bonding electrodes P_{B}, and are provided at positions overlapping the bonding electrodes P_{B} viewed from the Z-direction. Moreover, the via contact electrodes 742, which are each provided correspondingly to any of the bonding electrodes P_{B}, are provided at positions overlapping the wirings 741 viewed from the Z-direction. The wirings 751 are arranged in the X-direction and the Y-direction correspondingly to the bonding electrodes P_{B}, and extend in the Y-direction. A part of the wirings 751 are provided at positions overlapping the via contact electrodes 752 viewed from the Z-direction. Moreover, another part of the wirings 751 are provided at positions overlapping the via contact electrodes 742 viewed from the Z-direction.

### Other Embodiments

That concludes description of the semiconductor memory devices according to the first through seventh embodiments. However, the semiconductor memory devices according to these embodiments are merely exemplifications, and their specific configurations, and so on, may be appropriately adjusted.

For example, in the semiconductor memory devices according to the third through seventh embodiments, the gap 203 (FIG. 60) may be provided between a plurality of the word lines WL arranged in the Z-direction, similarly to in the second embodiment.

Moreover, the semiconductor memory device according to the third embodiment may comprise the capacitor structure 130 (FIGS. 4 and 5) instead of the capacitor structure 330 (FIGS. 61 and 62). In this case, the semiconductor memory device according to the third embodiment may comprise the insulating layer 430 (FIGS. 123 and 124), similarly to in the fourth embodiment. The semiconductor memory devices according to the fifth through seventh embodiments too may similarly comprise the insulating layer 430.

Moreover, the semiconductor memory devices according to the fifth through seventh embodiments may comprise the memory layer ML₃ (FIGS. 61 and 62) similar to in the third embodiment, instead of the memory layer ML similar to in the first embodiment.

Moreover, the semiconductor memory device according to the seventh embodiment may comprise the via wiring 601 and the wiring 603 (FIGS. 128 to 130), instead of the via wiring 501 and the wiring 503.

Moreover, in the semiconductor memory devices according to the first through seventh embodiments, the via wirings 104, 304 functioning as the bit line include a conductive oxide such as indium tin oxide (ITO). However, such a conductive oxide may be included in the transistor structures 110, 310, rather than in the via wirings 104, 304 extending in the Z-direction. Moreover, the via wirings 104, 304 and the transistor structures 110, 310 may include another material, and so on.

Moreover, in the semiconductor memory devices according to the first through seventh embodiments, the conductive layers 113, 313 functioning as the gate electrode of the transistor TrC may face only one of the upper surface and lower surface, of the semiconductor layers 111, 311 functioning as the channel region of the transistor TrC.

Moreover, in the above description, there is described an example where the capacitor CpC is adopted as the memory portion connected to the transistor structures 110, 310. However, the memory portion need not be the capacitor CpC. For example, the memory portion may be one that includes a ferroelectric material, a ferromagnetic material, a chalcogen material of the likes of GeSbTe, or other material, and that utilizes characteristics of these materials to store data. For example, any of these materials may be included in an insulating layer between the electrodes forming the capacitor CpC, in any of the structures described above.

Moreover, the methods of manufacturing the semiconductor memory devices according to the first through seventh embodiments, too, may be appropriately adjusted. For example, an order of any two of the above-mentioned steps may be switched, or any two of the above-mentioned steps may be simultaneously executed.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a plurality of memory layers arranged in a first direction intersecting with a surface of the substrate; and
a first via wiring extending in the first direction, wherein
the plurality of memory layers each comprises:
a first semiconductor layer electrically connected to the first via wiring;
a first gate electrode facing surfaces on one side and the other side in the first direction, of the first semiconductor layer;
a memory portion which is provided on one side in a second direction intersecting with the first direction with respect to the first semiconductor layer, and is electrically connected to the first semiconductor layer; and
a first wiring which is provided on the other side in the second direction with respect to the first semiconductor layer, is electrically connected to the first gate electrode, and extends in a third direction intersecting with the first direction and the second direction.

2. The semiconductor memory device according to claim 1, wherein
the first gate electrode faces surfaces on one side and the other side in the third direction, of the first semiconductor layer.

3. The semiconductor memory device according to claim 1, wherein
in a cross section extending in the second direction and the third direction, and including parts of the first via wiring, the first semiconductor layer, and the first gate electrode, the first semiconductor layer surrounds the first via wiring.

4. The semiconductor memory device according to claim 1, wherein
a gap is provided between a plurality of the first wirings arranged in the first direction correspondingly to the plurality of memory layers.

5. The semiconductor memory device according to claim 1, wherein
a position in the second direction of an end portion on a first wiring side in the second direction of the first gate electrode is provided between a position in the second direction of an end portion on one side in the second direction of the first via wiring and a position in the second direction of an end portion on the other side in the second direction of the first via wiring.

6. The semiconductor memory device according to claim 1, wherein
the memory portion comprises:
a first electrode electrically connected to the first semiconductor layer;
a second electrode facing the first electrode; and
a first insulating layer provided between the first electrode and the second electrode.

7. The semiconductor memory device according to claim 6, wherein
the memory portion comprises:
a first conductive layer which is included in the second electrode;
a second conductive layer which is included in the first electrode, and faces side surfaces on one side and the other side in the first direction of the first conductive layer, and side surfaces on one side and the other side in the third direction of the first conductive layer; and
a third conductive layer which is included in the second electrode, and faces side surfaces on one side and the other side in the first direction of the second conductive layer, and side surfaces on one side and the other side in the third direction of the second conductive layer.

8. The semiconductor memory device according to claim 7, wherein
a second insulating layer is provided between two of the second conductive layers corresponding to two of the memory layers adjacent in the first direction, the second insulating layer contacting the two of the second conductive layers.

9. The semiconductor memory device according to claim 1, comprising
a memory cell array, wherein
the memory cell array comprises:
a plurality of sub-memory cell arrays arranged in the first direction; and
a second via wiring extending in the first direction,
the plurality of sub-memory cell arrays each comprises:
the plurality of memory layers;
a transistor layer provided on one side in the first direction with respect to the plurality of memory layers; and
the first via wiring, and
the transistor layer comprises:
a second semiconductor layer which is electrically connected between the first via wiring and the second via wiring;
a second gate electrode which faces surfaces on one side and the other side in the first direction, of the second semiconductor layer; and
a second wiring which is provided at a position overlapping the first wiring viewed from the first direction, is electrically connected to the second gate electrode, and extends in the third direction.

10. The semiconductor memory device according to claim 9, comprising
a plurality of memory chips arranged in the first direction, wherein
the plurality of memory chips each include one of the plurality of sub-memory cell arrays.

11. The semiconductor memory device according to claim 1, wherein
the memory portion is a capacitor.

12. The semiconductor memory device according to claim 1, wherein
the first semiconductor layer includes: at least one element of gallium (Ga) and aluminum (Al); indium (In); zinc (Zn); and oxygen (O).

13. A semiconductor memory device comprising:
a substrate;
a plurality of memory layers arranged in a first direction intersecting with a surface of the substrate; and
a first via wiring extending in the first direction, wherein
the plurality of memory layers each comprises:
a first semiconductor layer electrically connected to the first via wiring;
a first gate electrode facing the first semiconductor layer;
a memory portion which is provided on one side in a second direction intersecting with the first direction with respect to the first semiconductor layer, and is electrically connected to the first semiconductor layer; and
a first wiring which is provided on the other side in the second direction with respect to the first semiconductor layer, is electrically connected to the first gate electrode, and extends in a third direction intersecting with the first direction and the second direction,
the memory portion comprises:
a first electrode electrically connected to the first semiconductor layer;
a second electrode facing the first electrode; and
a first insulating layer provided between the first electrode and the second electrode,
the memory portion comprises:
a first conductive layer which is included in the second electrode;
a second conductive layer which is included in the first electrode, and faces side surfaces on one side and the other side in the first direction of the first conductive layer, and side surfaces on one side and the other side in the third direction of the first conductive layer; and
a third conductive layer which is included in the second electrode, and faces side surfaces on one side and the other side in the first direction of the second conductive layer, and side surfaces on one side and the other side in the third direction of the second conductive layer, and
a second insulating layer is provided between two of the second conductive layers corresponding to two of the memory layers adjacent in the first direction, the second insulating layer contacting the two of the second conductive layers.

14. The semiconductor memory device according to claim 13, wherein
the memory portion is a capacitor.

15. The semiconductor memory device according to claim 13, wherein
the first semiconductor layer includes: at least one element of gallium (Ga) and aluminum (Al); indium (In); zinc (Zn); and oxygen (O).

16. A semiconductor memory device comprising
a substrate and a memory cell array, wherein
the memory cell array comprises:
a plurality of sub-memory cell arrays arranged in a first direction intersecting with a surface of the substrate; and
a first bit line extending in the first direction,
the plurality of sub-memory cell arrays each comprises:
a plurality of memory layers arranged in the first direction;
a transistor layer provided on one side in the first direction with respect to the plurality of memory layers; and
a second bit line extending in the first direction,
the plurality of memory layers each comprising:
a first semiconductor layer electrically connected to the second bit line;
a first gate electrode facing the first semiconductor layer;
a memory portion which is provided on one side in a second direction intersecting with the first direction with respect to the first semiconductor layer, and is electrically connected to the first semiconductor layer; and
a first wiring which is provided on the other side in the second direction with respect to the first semiconductor layer, is electrically connected to the first gate electrode, and extends in a third direction intersecting with the first direction and the second direction, and
the transistor layer comprises:
a second semiconductor layer which is electrically connected between the first bit line and the second bit line;
a second gate electrode which faces the second semiconductor layer; and
a second wiring which is provided at a position overlapping the first wiring viewed from the first direction, is electrically connected to the second gate electrode, and extends in the third direction.

17. The semiconductor memory device according to claim 16, comprising
a plurality of memory chips arranged in the first direction, wherein
the plurality of memory chips each include one of the plurality of sub-memory cell arrays.

18. The semiconductor memory device according to claim 16, wherein
the memory portion is a capacitor.

19. The semiconductor memory device according to claim 16, wherein
the first semiconductor layer includes: at least one element of gallium (Ga) and aluminum (Al); indium (In); zinc (Zn); and oxygen (O).
